(19) United States
(12) Patent Application Publication
(10) Pub. No.: US 2011/0001179 A1
(43) Pub. Date: Jan. 6, 2011

(54) SEMICONDUCTOR DEVICE AND MANUFACTURING METHOD OF THE SAME

(75) Inventors: Itaru YANAGI, Kunitachi (JP); Digh HISAMOTO, Kokubunji (JP); Daisuke OKADA, Kunitachi (JP); Atushi YOSHITOMI, Itami (JP); Yasufumi MORIMOTO, Nishinomiya (JP); Toshiyuki MINE, Fussa (JP)

Correspondence Address: MATTINGLY & MALUR, P.C., 1800 DIAGONAL ROAD, SUITE 370, ALEXANDRIA, VA, 22314, US

(73) Assignee: RENESAS ELECTRONICS CORPORATION, Kanagawa (JP)

(21) Appl. No.: 12/820,468

(22) Filed: Jun. 22, 2010

(30) Foreign Application Priority Data
Jul. 3, 2009 (JP) JP2009-158497

(51) Int. Cl. H01L 27/115; H01L 29/788

(52) U.S. Cl. 257/316; 257/315; 257/E29.3; 257/324; 257/E27.103

(57) ABSTRACT

In a non-volatile memory in which charge is injected from a gate electrode to a charge accumulating layer, charge injection efficiency, charge retention characteristic and reliability are all improved compared with a conventional gate structure. In a nonvolatile memory which carries out write/erasure by changing the total charge amount by injecting electrons and holes into a silicon nitride film which makes up a charge accumulating layer, in order to highly efficiently carry out charge injection from a gate electrode, the gate electrode of a memory cell is made up of a two-layer film of a non-doped polysilicon layer and a metal material electrode layer.

### CROSS-REFERENCE TO RELATED APPLICATION

The present application claims priority from Japanese Patent Application No. 2009-158497 filed on Jul. 3, 2009, the content of which is hereby incorporated by reference to this application.

### TECHNICAL FIELD OF THE INVENTION

The present invention relates to a semiconductor device including a non-volatile memory and a manufacturing method of the same. More particularly, it relates to a technology effectively applied to a non-volatile memory having a MONOS structure and a manufacturing method of the same.

### BACKGROUND OF THE INVENTION

Nowadays, the large scale integration (LSI) in which semiconductor elements are integrated is used in control of various systems and is becoming an infrastructure to support society. The operation of LSI today is based on the execution of arithmetic processing in accordance with programs. Therefore, the capability of storing programs is an essential requirement in many cases, and as a semiconductor element therefor, a non-volatile memory which is one of semiconductor memories incorporated in the LSI is becoming extremely important. In order to use the LSI in various applications, programs have to be restructured for these applications. Therefore, the non-volatile memory which is rewritable and retains stored information even when the power source of the LSI is turned off can be said to be essential.

A so-called floating gate type memory and a memory using insulating films as a charge accumulating layer are known as typical non-volatile memories. Particularly, the latter memory, in which the insulating films are stacked and the charge is accumulated in their interfaces and the traps and others of the films, does not have to form a new conductive layer like the floating gate type memory, and therefore, it is known that the memory can be formed with good compatibility with the complementary metal oxide semiconductor (CMOS)-LSI process. The stacked layer of silicon nitride films and silicon oxide films is widely used as the insulating films to be the charge accumulating layer because it can achieve both charge retention characteristic and rewriting characteristic. Such a non-volatile memory having the stacked insulating films is commonly called a metal-oxide-nitride-oxide-semiconductor (MONOS) type memory.

A typical example of the MONOS type memory is a two-transistor cell in which a memory transistor and a select transistor are connected in series. The memory transistor uses the Fowler-Nordheim (FN) tunnel current and direct tunnel current generated by applying a bias between a channel and a gate electrode, and injection/discharge of the electric charge is carried out by the entire channel surface.

However, the above-described MONOS type memory is required to have a sufficient charge retention characteristic while performing the injection/discharge of the electric charge, which causes the various problems. For example, in practice, when the thickness of the stacked insulating films is increased to sufficiently ensure the charge retention characteristic, write/erasure becomes difficult, and the time of write/erasure therefore exceeds a practical range.

For its solution, a method of rewriting stored information by injecting two types of electric charge having different signs (electrons and holes) by using hot carriers instead of discharging electric charge has been proposed in U.S. Pat. No. 6,215,148 (Patent Document 1) and others. This enables efficient injection of electric charge by injecting the hot carriers even in the case of a thick insulating film. According to this method, since electrons and holes can be locally injected alternately, different charge injection states can be generated at end portions in the channel direction of a planar type MOS transistor, that is, at end portions of a source and a drain and can be read as charge information.

A MONOS type memory employing the above-described hot carrier injection method basically employs the device structure of a MOS transistor, and the gate insulating film thereof, which is commonly a silicon oxide film, is replaced by three layers of insulating films, that is, a silicon oxide film, a silicon nitride film and a silicon oxide film. Also, conceivable examples of a forming method of a memory array include a method of forming sources and drains below a thick isolation oxide film and a method of forming linear sources and drains in the extending directions of gate electrodes so as to use them as wiring. In any memory arrays, when attention is focused on one memory cell, basic memory cell operations are similar in many cases and are described as follows.

The planar arrangement and the cross-sectional structure of the above-described MONOS type memory are shown in FIG. 1 to FIG. 5. In FIG. 1 to FIG. 5, the reference numeral 1 denotes a silicon substrate, the reference numerals 20 and 30 denote diffusion layers making up a source and a drain, the reference numerals 91 and 94 denote silicon oxide films, the reference numeral 92 denotes a silicon nitride film, and the reference numeral 50 denotes a gate electrode made up of a doped polysilicon layer. In FIG. 1, the reference numeral 61 denotes contacts, the reference numeral 99 denotes an active region, and WL denotes a word line.

A writing operation, an erasing operation and a reading operation of the above-described MONOS type memory will be described with reference to FIG. 2 to FIG. 5. Herein, the drawings of FIG. 2 to FIG. 5 show the cross-sectional views of the line A-A of FIG. 1.

In the writing operation, as shown in FIG. 2, 15 V is applied to the gate electrode 50 (word line WL), 0 V is applied to the diffusion layer 20 (bit line BL1), and 5 V is applied to the diffusion layer 30 (bit line BL2). The electrons accelerated by the electric field of a channel get in a hot carrier state and are injected into the silicon nitride film 92 (charge accumulating portion) which is in the vicinity of the end portion of the diffusion layer 30 (bit line BL2). It is known that the avalanche phenomenon is used or the substrate bias acceleration is used as a method of generating the hot carriers.

In the erasing operation, as shown in FIG. 3, −6 V is applied to the gate electrode 50 (word line WL), 0 V is applied to the diffusion layer 20 (bit line BL1), and 6 V is applied to the diffusion layer 30 (bit line BL2). Holes are generated at the end portion of the diffusion layer 30 (bit line BL2) by the interband tunnel phenomenon, and the holes are injected into the silicon nitride film 92 (charge accumulating portion) by accelerating them by the bias between the diffusion layer 30 (bit line BL2) and the silicon substrate 1.

In the reading operation, as shown in FIG. 4, 3 V is applied to the gate electrode 50 (word line WL), 1 V is applied to the diffusion layer 20 (bit line BL1), and 0 V is applied to the diffusion layer 30 (bit line BL2), thereby reading the amount of channel current that flows in the direction of the arrow shown in FIG. 4 as accumulated charge information. More specifically, when electrons have been injected into the silicon nitride film 92 (charge accumulating portion), the threshold voltage thereof is high, and the channel current does not flow. On the other hand, when holes have been injected, the threshold voltage is low, and a large channel current flows.

In the case of the above-described MONOS type memory, the threshold voltage is strongly affected by the charge injected into the silicon nitride film 92 (charge accumulating portion) that is in the vicinity of the end portion of the diffusion layer to be the source side in reading, and the threshold voltage depends not so much on the charge state of the silicon nitride film 92 (charge accumulating portion) that is in the vicinity of the end portion of the diffusion layer to be the drain side. Therefore, by using the above-described diffusion layer 20 and diffusion layer 30 in a switched manner, one memory cell can be used as 2 bits. FIG. 5 shows the state in which electrons have been injected into the silicon nitride film 92 (charge accumulating portion) of the diffusion layer 20 (bit line BL1) side, holes have been injected into the silicon nitride film 92 of the diffusion layer 30 (bit line BL2) side, and the diffusion layer 20 (bit line BL1) is being read. Herein, the state in which the holes (shown by white circles) are accumulated in the silicon nitride film 92 (charge accumulating portion) of the diffusion layer 20 (BL1) side, and the electrons (shown by black circles) are accumulated in the silicon nitride film 92 of the diffusion layer 30 (bit line BL2) side is shown.

U.S. Pat. No. 5,969,383 (Patent Document 2) and U.S. Pat. No. 6,477,084 (Patent Document 3) disclose a memory cell called a split gate structure as another example of the MONOS type memory. In this memory cell, two MOS transistors (select transistor 40 and memory transistor 41) basically based on n channel type MOS transistors are connected with each other in the state in which the memory transistor 41 is vertically stacked by the side of the select transistor 40. FIG. 8 shows an equivalent circuit of this memory cell. Also, FIG. 6 and FIG. 7 are a plan view and a cross-sectional view of a memory cell corresponding to the circuit shown in FIG. 8, and FIG. 7 is a cross-sectional view taken along the line B-B of FIG. 6. The reference numerals 21 and 31 in FIG. 7 denote n-type diffusion layers, the reference numeral 90 denotes a gate insulating film made up of a silicon oxide film, the reference numeral 52 denotes a select gate, the reference numeral 95 denotes a gate insulating film which serves as a charge accumulating film, the reference numeral 55 denotes a memory gate, and the reference numeral 96 denotes sidewalls made up of silicon oxide films. Also, the reference numeral 52 of FIG. 6 corresponds to the select gate, 55 corresponds to the memory gate, and 99 corresponds to an active region.

Herein, the operation method of the memory cell will be first described, and the manufacturing method thereof and others will be described in detail when embodiments and the problems to be solved by the present invention are described. Moreover, a circuit configuration of a memory array using the memory cell is shown in FIG. 9. The gate electrodes (select gate 52 and memory gate 55) of the select transistor and the memory transistor make up the word lines denoted by SGL and MGL, respectively, the diffusion layer 30 of the select transistor makes up a bit line, and the diffusion layer 20 of the memory transistor makes up a source line.

Typical writing/erasing operations of the above-described memory cell are shown in FIG. 10 and FIG. 11. The gate insulating film 95 of the memory gate 55 has the MONOS structure in which a silicon nitride film is sandwiched by two layers of silicon oxide films. The gate insulating film 90 of the select gate 52 is made up of a silicon oxide film. The diffusion layers 20 and 30 are formed by ion implantation of an impurity respectively using the select gate 52 and the memory gate 55 as masks. The four states, that is, (1) write, (2) erasure, (3) retention, and (4) read are conceivable as basic operations of the memory cell. However, the names of the four states are used as typical examples, and write and erasure can be called by the opposite names. Also, although the operations are described by using typical ones, various different operations are conceivable. Herein, a memory cell made up of two n channel type MOS transistors (select transistor and memory transistor) will be described, but even in the case of a memory cell made up of two p channel type MOS transistors, the memory cell can be similarly described in terms of principle.

First, the writing operation is shown in FIG. 10. A positive electric potential is applied to the diffusion layer 20 of the memory gate 55 side, and the same ground electric potential as that of the silicon substrate 1 is applied to the diffusion layer 30 of the select gate 52 side. A high gate overdrive voltage with respect to the silicon substrate 1 is applied to the memory gate 55, thereby turning the channel below the memory gate 55 to an ON state. Herein, the electric potential of the select gate 52 is caused to have the value higher than the threshold voltage by about 0.1 V to 0.2 V, thereby achieving the ON state. At this point, since the strongest electric field is generated in the vicinity of the boundary between the select gate 52 and the memory gate 55, many hot electrons are generated and injected into the gate insulating film 95 of the memory gate 55 side. The state of generation of carriers caused by impact ionization is denoted by the reference numeral 80. Also, electrons are shown by black circles and holes are shown by white circles. This phenomenon is known as source side injection (SSI).

A characteristic of the hot electron injection in this method is that, since the electric field is concentrated in the vicinity of the boundary between the select gate 52 and the memory gate 55, the injection is intensively carried out to the end portion of the memory gate 55 on the select gate 52 side. Further, although a charge retention layer is made up of a conductive film in a floating gate type memory, since electrons are accumulated in the insulating film in the insulating film type memory, the electrons are retained in an extremely narrow region.

Next, the erasing operation is shown in FIG. 11. A negative electric potential is applied to the memory gate 55, and a positive electric potential is applied to the diffusion layer 30 of the memory gate 55 side, so that strong inversion occurs in the region of the end portion of the diffusion layer 30 where the memory gate 55 is overlapped with the diffusion layer 30. By this means, the interband tunnel phenomenon is caused, and hot holes 81 are generated. In this memory cell, the generated holes are accelerated in the direction of the channel, attracted by the bias of the memory gate 55, and injected into the gate insulating film 95, whereby the erasing operation is carried out. Moreover, the generated holes generate secondary electron-hole pairs 82. These carriers are also injected into the gate insulating film 95. In other words, the threshold voltage of the memory gate 55, which has been increased by the charge of the electrons, is lowered by the charge of the injected holes.

In the charge retention, charge is retained as the charge of the carriers injected into the gate insulating film 95. The barrier film (silicon oxide film) in the gate insulating film 95 has a high potential barrier, and the charge is retained well.

Also, in the reading, a positive electric potential is applied to the diffusion layer 20 of the select gate 52 side, and a positive electric potential is applied to the select gate 52, thereby turning the channel below the select gate 52 to the ON state. Herein, an appropriate memory gate electric potential capable of determining the threshold voltage difference of the memory gate 55 imparted by the write/erasure state (in other words, an intermediate electric potential between the threshold voltage of the write state and the threshold voltage of the erasure state) is applied, thereby reading the retained charge information as a current.

In “2005 IEEE, International Electron Device Meeting, Technical Digest” pp. 547-550 (Non-Patent Document 1), the technique of injecting holes without using hot carriers is described. In a conventional stacked gate insulating film structure in which a silicon oxide film is used as a barrier layer, the tunnel injection of holes from a channel is impossible because the silicon oxide film formed between a silicon nitride film and a silicon substrate is thick. Therefore, in Non-Patent Document 1, instead of the silicon oxide film, a stacked film of an extremely thin silicon oxide film, a silicon nitride film and a silicon oxide film is formed so that holes can easily tunnel from the silicon substrate side when an electric field is applied thereto.

Japanese Patent Application Laid-Open Publication No. 2004-303918 (Patent Document 4) discloses the technique in which the structure in which a silicon oxide film, a silicon nitride film and a silicon oxynitride (SiON) film are stacked in this order from the silicon substrate side is employed as the structure of a gate insulating film, and holes are injected from the gate electrode side by applying a positive voltage to a gate electrode.

FIG. 12 shows a cross-sectional view of the memory cell. The reference numeral 20 denotes a diffusion layer serving as a source, the reference numeral 30 denotes a diffusion layer serving as a drain, the reference numeral 91 denotes the silicon oxide film, the reference numeral 92 denotes the silicon nitride film, the reference numeral 93 denotes the silicon oxynitride film, and the reference numeral 50 denotes the gate electrode. The charge accumulating film is the silicon nitride film 92. In the writing, electrons are injected (hot electron injection) from the silicon substrate 1, and in the erasure, holes are injected from the gate electrode 50. According to this method, by using silicon oxynitride (SiON) that has a smaller band gap than that of silicon oxide and has a low barrier with respect to holes to form the insulating film of the gate electrode 50 side, the FN (Fowler-Nordheim) tunneling of the holes can be performed with a small electric field in the erasure.

Generally, it is conceivable to improve the state of the interface between a polycrystalline silicon film making up the gate electrode 50 and the silicon oxynitride film 93 by sandwiching a thin silicon oxide film of about 1 nm at the interface between the gate electrode 50 and the silicon oxynitride film 93 (not shown). In this case, the thin silicon oxide film of about 1 nm does not serve as a main factor to determine the transmission rate in the hole injection because holes can directly tunnel therethrough from the gate electrode 50. The main factor that determines the injection efficiency of holes is the film thickness of the silicon oxynitride film 93 and the band offset with respect to the holes.

Japanese Patent Application Laid-Open Publication No. 2008-211162 (Patent Document 5) discloses the technique in which the stacked structure of a non-doped polysilicon layer (though it is difficult to form a completely non-doped polysilicon layer, a deposited polysilicon layer from which impurities are intentionally eliminated is called a non-doped polysilicon layer, and the concentration and others thereof are noted in accordance with needs in the present specification) and a p⁺ type polysilicon layer containing a high-concentration p type impurity disposed in this order from the side close to a memory insulating film is employed as the gate structure, thereby enhancing the injection efficiency of holes in the hole injection from the gate. This utilizes the phenomenon that the band of the non-doped silicon layer bends when a positive voltage is applied to the gate. When the band of the non-doped silicon layer bends, a quantum level is formed at the interface between the memory insulating film and the gate, the height of the barrier of the insulating film viewed from holes is lowered by the amount of the energy of the quantum level, and highly efficient hole injection is carried out. According to this method, highly efficient hole injection from the gate can be carried out even without reducing the thickness of the barrier insulating film between the gate electrode and the charge accumulating layer and lowering the barrier.

### SUMMARY OF THE INVENTION

As described above, the carrier injection using hot carriers has the characteristic that injection can be efficiently carried out even if the insulating film between the silicon substrate 1 and the silicon nitride film which is the charge accumulating layer is thick. This is because the energy of the hot carriers has the energy that is approximately comparable to the magnitude of the barrier potential of the insulating film measured from above the silicon band. However, the injection of the carriers in the high-energy state from the silicon substrate 1 side via the insulating film causes many defects at the interface between the channel of the silicon substrate 1 and the gate insulating film 95, and when carriers are trapped thereat in the reading, faults in the reading such as deterioration and variation of the threshold voltage are caused.

Particularly, since the band offset of the silicon oxide film, which is the gate insulating film 90 immediately above the channel, with respect to silicon is higher to holes than to electrons, hot hole injection requires the holes with higher energy than those of hot electron injection. Therefore, when the hot hole injection is employed, the damage imparted to the interface between the channel and the insulating film is more serious than that of the hot electron injection.

Also, it is known that, since injection of carriers is locally carried out in hot carrier injection methods such as source side injection (SSI) and band-to-band tunnel hot hole injection (BTBTHH injection), the carriers injected into the charge accumulating layer (silicon nitride film) diffuse with time and cause variation in the threshold voltage and deterioration of the charge retention characteristic.

These problems are caused because the channel interface is deteriorated when holes are injected from the silicon substrate by using hot carriers. Also, from another viewpoint, the problems are caused because the holes are locally injected from a high-electric-field position. Therefore, when holes are to be injected from the silicon substrate, the measures for enabling the nonlocal injection of holes with low energy while maintaining a film thickness that ensures a sufficient charge retention characteristic are necessary.

Furthermore, the number of carriers generated when BTBTHH injection is carried out is extremely large, and most of them flow to the silicon substrate, and therefore, a large current has to be supplied in the hole injection. Therefore, the area of a charge pump in a peripheral circuit region other than the memory cell part is increased, which makes it difficult to reduce the module size.

The above-described Non-Patent Document 1 is known as a method for solving the above-described problem. However, since the silicon substrate side has to be used as a channel in the reading, the silicon oxide film has to be formed to be thick in order to maintain a channel characteristic and suppress variation in the threshold voltage caused by disturbances. Moreover, since charge is moved through the barrier film in the injection of holes, holes pass through the channel interface. As a result, deterioration in the interface characteristic is also inevitable. Furthermore, it is conceived that carriers are trapped by the silicon nitride film during the writing/erasing operation in the stacked film of the extremely thin silicon oxide film, the silicon nitride film and the silicon oxide film, and variation in the threshold voltage due to detrapping of the carriers is inevitable.

A nonlocal hole injection from a gate electrode is conceivable as the nonlocal hole injection method that does not deteriorate the interface. However, since the valence band offset of silicon oxide and silicon is as high as 4.7 eV, if the insulating film below the gate electrode is a thick silicon oxide film, the hole injection from the gate electrode is difficult.

For its solution, in Patent Document 4, the structure in which a silicon oxide film, a silicon nitride film and a silicon oxynitride (SiON) film are stacked in this order from the silicon substrate side is employed as the structure of the gate insulating film.

However, in the case of the above-described document, hole injection from the gate electrode employs the method in which the holes which are not hot carriers are injected in the state in which a positive voltage is applied to the gate electrode, and therefore, the reduction in erasure efficiency due to electron injection from the silicon substrate in the hole injection from the gate electrode side is a problem. Particularly, when the film thickness of the insulating film between the gate electrode and the charge accumulating layer is thick or when the barrier of the insulating film to holes is high, the electron injection amount from the silicon substrate surpasses the injection amount of holes, and the erasure becomes difficult. Moreover, as a matter of course, in the hole injection not using hot carriers, the injection speed is slow compared with that using hot carriers, and the rewriting speed becomes slow.

In order to solve these problems and realize hole injection from the gate electrode at high efficiency, the thickness of the insulating film between the gate electrode and the charge accumulating layer has to be reduced, or the valence band offset corresponding to the barrier for holes in the gate electrode has to be lowered. However, both the reduction in the band offset and the thickness reduction of the insulating film between the gate electrode and the charge accumulating layer deteriorate the retention characteristic of electrons and holes trapped in the silicon nitride film.

As is understood from the above-described Patent Documents, in a nonlocal hole injection method, the hole injection from the gate electrode is effective to suppress the deterioration of the channel interface and reduce the current due to the erasure. Moreover, it can also be understood that it is preferable to employ the stacked structure of a non-doped polysilicon layer and an impurity-doped p⁺ type polysilicon layer for the gate in order to increase the efficiency of hole injection from the gate without impairing the retention characteristic of the memory. This stacked gate structure has a merit that it can be formed without major changes in processes such as introduction of new materials to the gate because it can be formed only by providing two layers, that is, the non-doped polysilicon layer and the p⁺ type polysilicon layer and performing the activation annealing by laser annealing in the device formation. The degree of the effect thereof is extremely large, and highly-efficient hole injection that is faster than that of a single-layer p⁺ type gate by one or more orders of magnitude can be realized.

However, when employing the stacked structure of the non-doped polysilicon layer and the impurity-doped p⁺ type polysilicon as the gate structure, attention has to be paid for a thermal process in the device formation.

Hereinafter, problems will be specifically described along with an example of the MONOS formation process.

FIG. 13 to FIG. 17 show the process in the case in which a stacked structure of non-doped polysilicon and impurity-doped polysilicon is employed for a gate in a so-called one-transistor type MONOS memory (called NROM type) as shown in FIG. 1 to FIG. 5. The descriptions will be given with reference to the A-A cross section of FIG. 1.

First, as shown in FIG. 13, an isolation region (not shown) is formed in a main surface of a p type silicon substrate 1 by using a known shallow trench isolation (STI) process. Then, ion implantation of boron and activation annealing treatment are carried out, thereby forming a p type well region (not shown) in the surface of the silicon substrate 1. Next, a gate insulating film 95 is formed on the silicon substrate 1. The gate insulating film 95 is made up of a four-layer film of a silicon oxide film 91, a silicon nitride film 92, a silicon oxynitride film 93 and a silicon oxide film 94.

The four-layer film is formed by, for example, forming the silicon oxide film 91 having a film thickness of 4 nm by thermally oxidizing the surface of the silicon substrate 1 and then sequentially depositing the silicon nitride film 92 having a film thickness of 6 nm and the silicon oxynitride film 93 having a film thickness of 5 nm on the silicon oxide film 91 by using the chemical vapor deposition (CVD) method. The deposition of the silicon nitride film 92 by the CVD method uses SiH₂Cl₂+NH₃ as a source gas. Subsequently, an oxidizing agent (N₂O) is added to the source gas, and the flow rate of NH₃ is regulated, thereby forming the silicon oxynitride film 93. The silicon oxynitride film 93 has a characteristic that the band gap thereof is larger than that of the silicon nitride film 92. Herein, the composition ratio of oxygen and nitrogen in the silicon oxynitride film 93 is 1:1. Then, the thin silicon oxide film 94 having a film thickness of about 1 nm is formed on the silicon oxynitride film 93. The extremely-thin silicon oxide film 94 like this can be formed by the In-Situ Steam Generation (ISSG) oxidation to the surface of the silicon oxynitride film 93. The film thickness of the silicon oxynitride film 93 is determined in consideration of the reduction in film thickness due to the formation of the silicon oxide film 94. The four-layer insulating film making up the gate insulating film can be obtained for example through the process above.

Then, a non-doped amorphous silicon layer is deposited to about 6 nm. Thereafter, the amorphous silicon layer is crystallized by carrying out thermal treatment at 900° C. in an N₂ atmosphere for 30 minutes, thereby forming a polysilicon layer 54. Next, an amorphous silicon layer 48 which is doped with boron in the film formation is deposited to 100 nm. The concentration of boron is 7×10²⁰/cm³. Herein, the reason why the amorphous silicon layer deposited on the gate insulating film 95 is crystallized into the polysilicon layer 54 by N₂ annealing is that, compared with amorphous silicon, polysilicon is more capable of suppressing impurity diffusion from the boron-doped amorphous silicon layer 48 deposited thereon.

Next, as shown in FIG. 14, a gate electrode made up of the amorphous silicon layer 48 and the polysilicon layer 54 is formed by etching using a resist as a mask, and the gate insulating film 95 is subjected to wet etching. Then, arsenic is ion-implanted to the surface of the silicon substrate 1, thereby forming diffusion layers 20 and 30 to be n⁻ type diffusion layers. The n⁻ type diffusion layers 20 and 30 are formed for causing the memory cell to have a lightly doped drain (LDD) structure. Note that, before gate processing, an oxide film is deposited to about 50 to 100 nm on the amorphous silicon layer 48 by the CVD method which is capable of carrying out the deposition at a low temperature, and then gate processing is carried out. By this means, the implanted arsenic ions stop in the oxide film, and the ions can be prevented from being implanted into the silicon of the gate. If the CVD film is deposited on the amorphous silicon layer 48, the oxide film on the gate is simply removed before the silicide processing of FIG. 17.

Herein, the implantation energy of arsenic is 5 keV, and the dose amount thereof is 2×10¹⁵ atom/cm². Problems in the step of FIG. 14 will be described below.

The gate insulating film 95 includes a charge accumulating film and barrier films and is one of the most important parts of a memory that stores information by accumulated charge. Therefore, wet etching that causes small damage is desired to be used as the etching of the gate insulating film 95.

This is for the reasons that etching of the gate insulating film 95 by dry etching may damage end portions of the gate insulating film 95 and defects may occur in the silicon oxide film 91, the silicon oxynitride film 93 and the silicon oxide film 94 which are the barrier films, so that the defects may become a cause of leakage in the charge retention.

When the treatment is carried out by wet etching, first, the thin silicon oxide film 94 closest to the gate electrode is removed by hydrofluoric acid cleaning. Then, the silicon oxynitride film 93 is removed by using hot phosphoric acid or hydrofluoric acid. The silicon oxynitride film can be removed by hydrofluoric acid when the oxygen content thereof is high and can be removed by hot phosphoric acid when the oxygen content thereof is low. Alternatively, the film can be removed also by double etching treatment in which etching by hot phosphoric acid is carried out after etching by hydrofluoric acid. Then, the silicon nitride film 92, which is the charge accumulating film, is removed by hot phosphoric acid. In the etching of the silicon oxynitride film 93 and the silicon nitride film 92 by hot phosphoric acid, there is a problem that the silicon of the gate electrode is also reduced because hot phosphoric acid has the property of dissolving polysilicon and amorphous silicon. The reduction in the gate electrode due to the wet etching leads to variation in finishing among samples when many memories are formed, and as a result, the variation in the memory characteristics occurs.

For the solution of the above-described problems, when the hot phosphoric acid is used for the removal of the silicon oxynitride film 93 and the silicon nitride film 92 after the silicon oxide film 94 is removed by hydrofluoric acid, the sidewalls of the gate electrode have to be oxidized to about 3 to 5 nm as shown in FIG. 15 by carrying out thermal oxidation before the hot phosphoric acid treatment so as to form a silicon oxide film 89. Note that the silicon oxide film 94 is not shown because it is a thin film. The silicon nitride film and the silicon oxynitride film have a lower oxidation rate and a lower oxidation speed compared with those of silicon, and therefore, the films are oxidized to only about 1 to 2 nm by dry oxidation, and the oxidation rate of the silicon nitride film is about 60 to 70 percent of silicon even in ISSG oxidation or the like. Therefore, by carrying out the light etching using hydrofluoric acid after thermal oxidation is once carried out, the state in which the oxide film on the silicon oxynitride film 93 and the silicon nitride film 92 is removed while the silicon oxide film 89 is remaining on the sidewalls of the gate electrode as shown in FIG. 15 can be formed. When removal of the silicon oxynitride film and the silicon nitride film by hot phosphoric acid is carried out thereafter, the selectivity of the silicon oxide film and the silicon nitride film is high and the films are not reduced by hot phosphoric acid almost at all, and therefore, the silicon oxynitride film 93 and the silicon nitride film 92 can be etched while suppressing the reduction in the gate electrode.

Herein, since the thermal oxidation process requires a high temperature, there is a problem that the impurity (dopant) of the amorphous silicon layer 48 diffuses to the non-doped polysilicon layer 54 and the gate of the stacked structure cannot be formed.

When arsenic is implanted into the silicon substrate 1 for forming the n⁻ type diffusion layers 20 and 30 after the removal of the silicon nitride film 92 and before the etching of the silicon oxide film 91, the silicon oxide film 91 can be used as a through film of the ion implantation. Moreover, after the arsenic ion implantation, the silicon oxide film 91 is removed by hydrofluoric acid, and re-oxidation of about 1 nm in terms of the silicon oxide thickness is carried out. By this means, the part of the silicon oxide film 91, the silicon nitride film 92 and the silicon oxynitride film 93 that is exposed below the polysilicon gate can be thinly oxidized, the damage caused during the arsenic ion implantation can be recovered, and the reliability of the memory can be improved. If this step is introduced, however, since this step also requires a high temperature, there is a problem that the impurity (dopant) of the amorphous silicon layer 48 diffuses to the non-doped polysilicon layer 54 and the gate of the stacked structure cannot be formed.

Next, as shown in FIG. 16, after a silicon oxide film having a film thickness of 100 nm is deposited on the silicon substrate 1 by the CVD method, the silicon oxide film is subjected to anisotropic etching, thereby forming sidewalls 96 on the sidewalls of the gate. Subsequently, after arsenic and phosphorous are ion-implanted to the surface of the silicon substrate 1, activation is carried out to activate the arsenic and phosphorous, thereby forming diffusion layers 21 and 31 to be a source and a drain of the memory cell. Herein, when rapid thermal anneal (RTA) of conventional techniques is used in the activation annealing, a thermal load at 950° C. to 1000° C. for 10 seconds or more is applied. When the stacked structure of the non-doped polysilicon layer and the impurity-doped polysilicon is used as the gate electrode, the dopant diffuses from the impurity-doped polysilicon to the non-doped polysilicon layer also in this step due to thermal diffusion. Therefore, a process of rapid heating and rapid cooling of extremely short period of time is necessary, and activation of 1 msec or less using laser annealing or the like is required. When formation of the diffusion layers by laser annealing is carried out after the impurities are implanted into the silicon substrate, the diffusion layers expand merely to about several nm by laser annealing from the profile immediately after the implantation. Therefore, when ion implantation is carried out with reduced implantation energy so as to form a peak of the impurity concentration at a location near the surface of the silicon substrate, only shallow diffusion layers are formed and the diffusion layers are penetrated through in the later silicide step, or the portions up to the location near the junction parts of the diffusion layers and the p type silicon substrate are silicided. This causes the channel leakage currents and leakage currents to the silicon substrate in the memory operation and the transistor operation, which leads to the defective characteristics.

On the other hand, when activation by laser annealing is carried out after the impurities are implanted with increased implantation energy, the impurity concentration of the diffusion layers of the surface of the silicon substrate is lowered, which also causes the leakage currents to the silicon substrate and the channel leakage currents.

Therefore, when activation is carried out by using laser annealing, in order to obtain good memory transistor characteristics, the impurity implantation into the diffusion layers has to be carried out by multiple-level implantation so as to form a deep implantation profile having a high impurity concentration.

However, the impurity implantation into the silicon substrate with the increased implantation energy and the impurity implantation carried out multiple times increase the amount of the impurities which penetrate through the gate electrode in the implantation and are implanted also into the gate insulating film 95 therebelow, and the gate insulating film 95 is damaged. This causes defects in the barrier films which are sandwiching the charge accumulating film, and as a result, the retention characteristic of the memory may be impaired.

Moreover, the impurity implantation carried out multiple times with a high concentration may locally form an n type region in the p type gate, and problems may be caused in operation. Therefore, it is desirable to carry out the low-concentration implantation by which the largest value of the volume density of the impurity implantation profile becomes lower than the volume density of boron of the p type gate.

Moreover, since impurity diffusion is small in the activation by laser annealing, the impurity profiles at the pn junction parts between the silicon substrate and the channel and the diffusion layers become steep, and the leakage currents caused by gate induced drain leakage (GIDL) in the MONOS operation are increased. Further, the steep junction profiles of the diffusion layers cause the above-described erroneous write/erroneous erasure (disturbance) to non-selected cells in the write/erasure at the array operation.

Because of the above-described reasons, it is desirable that the implantation energy and the number of times of implantation for the formation of the diffusion layers are minimized and the diffusion layers having high-concentration broad profiles are formed by using thermal activation by conventional RTA. However, in the stacked structure of the non-doped silicon and impurity-doped silicon, the impurity therein diffuses to the non-doped silicon layer in the thermal process by RTA, and it is difficult to maintain the stacked gate structure.

Note that the Patent Document 5 describes a process (dummy gate process) in which a dummy memory gate is formed in advance, an impurity of diffusion layers is implanted with using the dummy memory gate as a mask, the activation annealing by RTA is carried out, and then the dummy memory gate is etched to form a true memory gate (stacked gate). When the dummy gate process is used, although the number of steps is increased, the above-described problem of the impurity implantation and the problem of the diffusion of the impurity in the stacked gate can be avoided because the thermal load of the diffusion layer activation by RTA is applied before the stacked gate is deposited.

With regard to the n type impurity implantation to the gate in the formation of the diffusion layers, when an oxide film is deposited on the boron-doped amorphous silicon layer 48 by the CVD method capable of carrying out the deposition at low temperature before the gate processing as described above, the implanted arsenic ions can be stopped in the oxide film and can be prevented from being implanted into the silicon of the gate although the gate height is increased.

Next, as shown in FIG. 17, a silicide layer 53 is formed on the surfaces of the amorphous silicon layer 48 and the diffusion layers 21 and 31 by a known salicide process. The silicide layer 53 is made of, for example, Co silicide.

It is known that there is the effect that the retention characteristic of a MONOS memory is improved by adding annealing treatment in a high-temperature H₂ atmosphere (about 700° C.) before the salicide process. However, this also cannot be applied when the impurity diffusion into the non-doped polysilicon layer 54 in the stacked gate is taken into consideration.

Next, after a thick interlayer insulating film is deposited on the silicon substrate 1, wiring is formed on the interlayer insulating film by a known wiring process. A MONOS type memory having a NROM structure (not shown) is completed through the above-described steps.

As described above, as a problem of the MONOS memory having the gate electrode made up of the stacked structure of the non-doped polysilicon layer and the impurity-doped polysilicon layer, the processes accompanied by high-temperature thermal treatment such as thermal oxidation, activation annealing by RTA and high-temperature H₂ annealing cannot be used after the formation of the memory gate, and as a result, there is a problem that it is difficult to improve the reliability of the memory.

If the dopant diffuses to the non-doped polysilicon layer through the high-temperature process and the gate becomes, for example, a p type single-layer gate, the high-speed erasure as described in Patent Document 5 and the tunnel hole injection from the gate in which erasure saturation Vth is also low cannot be realized.

Also, even when processes such as high-temperature thermal oxidation and annealing are eliminated and activation of the diffusion layers and the gate is carried out by laser annealing after the gate of non-doped polysilicon and impurity-doped polysilicon is deposited, the diffusion of the impurity into the non-doped polysilicon cannot be completely suppressed.

FIG. 18 shows a SIMS analysis result of a sample taken at the point when laser annealing at 1200° C. for 800 μsec is carried out after the non-doped polysilicon and the polysilicon doped with boron in the film formation are deposited. The broken line in FIG. 18 is the position of the junction surface of the non-doped polysilicon layer and the silicon layer doped with the impurity in the film formation. The boron concentration profile in the non-doped polysilicon layer is rapidly reduced at the interface between the boron-doped polysilicon layer and the non-doped polysilicon layer, and a low-concentration region from 1×10¹⁸/cm³ to 1×10¹⁹/cm³ is formed. However, there is a lower limit of the boron concentration in the non-doped silicon, and the diffusion cannot be suppressed to the concentration equal to or lower than 3×10¹⁸/cm³. This is due to the diffusion in the film formation of boron-doped polysilicon and the diffusion in the laser annealing. As a matter of course, if a low-concentration region of about 3×10¹⁸/cm³ can be formed, the hole injection more efficient than that of a p⁺ type single-layer gate is possible. However, efforts have to be made for achieving more highly efficient hole injection.

An object of the present invention is to provide the technique that enable highly-efficient tunnel hole injection from a gate in a memory cell which has undergone thermal treatment in high-temperature thermal treatment processes and common processes after formation of a memory gate so as to improve the performance and reliability of the memory.

The above and other objects and novel characteristics of the present invention will be apparent from the description of the present specification and the accompanying drawings.

The typical ones of the inventions disclosed in the present application will be briefly described as follows.

A semiconductor device according to one invention of the present application is a semiconductor device including a memory cell formed on a main surface of a semiconductor substrate of a first conductivity type, wherein the memory cell comprises: a gate electrode formed on the semiconductor substrate via a gate insulating film; and a source region and a drain region formed in the semiconductor substrate in a vicinity of the gate electrode and respectively made up of semiconductor regions of a second conductivity type, the gate insulating film is made up of at least an electric potential barrier film and a charge retaining film stacked on the electric potential barrier film, and the gate electrode includes a polysilicon layer having an impurity concentration of 5×10¹⁹/cm³ or less and a metal material electrode layer formed on the polysilicon layer.

The effects obtained by typical embodiments of the invention disclosed in the present application will be briefly described below.

In a non-volatile semiconductor memory in which carriers are injected from a gate, efficiency enhancement of the carrier injection and improvement in the reliability of the memory can be both achieved.

### BRIEF DESCRIPTIONS OF THE DRAWINGS

FIG. 1 is a plan view of a conventional MONOS type memory employing a hot carrier injection method;

FIG. 2 is a cross-sectional view showing a wiring operation of the conventional MONOS type memory employing the hot carrier injection method;

FIG. 3 is a cross-sectional view showing an erasing operation of the conventional MONOS type memory employing the hot carrier injection method;

FIG. 4 is a cross-sectional view showing a reading operation of the conventional MONOS type memory employing the hot carrier injection method;

FIG. 5 is a cross-sectional view showing a reading operation of a conventional MONOS type memory using one memory cell as 2 bits;

FIG. 6 is a plan view of a conventional split gate type MONOS memory;

FIG. 7 is a cross-sectional view of the conventional split gate type MONOS memory;

FIG. 8 is an equivalent circuit diagram of the conventional split gate type MONOS memory;

FIG. 9 is a circuit diagram of a memory array using the conventional split gate type MONOS memory;

FIG. 10 is a cross-sectional view showing a wiring operation of the conventional split gate type MONOS memory;

FIG. 11 is a cross-sectional view showing an erasing operation of the conventional split gate type MONOS memory;

FIG. 12 is a cross-sectional view of a conventional memory cell;

FIG. 13 is a cross-sectional view showing a manufacturing process of a conventional MONOS memory;

FIG. 14 is a cross-sectional view showing the manufacturing process of the MONOS memory continued from FIG. 13;

FIG. 15 is a cross-sectional view showing the manufacturing process of the MONOS memory continued from FIG. 14;

FIG. 16 is a cross-sectional view showing the manufacturing process of the MONOS memory continued from FIG. 15;

FIG. 17 is a cross-sectional view showing the manufacturing process of the MONOS memory continued from FIG. 16;

FIG. 18 is a graph showing a boron concentration profile of a non-doped polysilicon/p⁺ type polysilicon stacked gate obtained by SIMS analysis;

FIG. 19 is a cross-sectional view showing a manufacturing process of a semiconductor device according to the first embodiment of the present invention;

FIG. 20 is a cross-sectional view showing the manufacturing process of the semiconductor device continued from FIG. 19;

FIG. 21 is a cross-sectional view showing the manufacturing process of the semiconductor device continued from FIG. 20;

FIG. 22 is a cross-sectional view showing the manufacturing process of the semiconductor device continued from FIG. 21;

FIG. 23 is a cross-sectional view showing the manufacturing process of the semiconductor device continued from FIG. 22;

FIG. 24 is a band diagram for describing the principle of an erasing operation according to the first embodiment of the present invention;

FIG. 25 is a band diagram for describing the principle of an erasing operation in a conventional MONOS having a stacked gate electrode structure of non-doped polysilicon and p⁺ type polysilicon;

FIG. 26 is a graph of experimental results of an erasing characteristic showing the effects of the present invention;

FIG. 27 is a plan view of a MONOS type memory having a split gate according to the second embodiment of the present invention;

FIG. 28 is a cross-sectional view showing a manufacturing process of a semiconductor device according to the second embodiment of the present invention;

FIG. 29 is a cross-sectional view showing the manufacturing process of the semiconductor device continued from FIG. 28;

FIG. 30 is a cross-sectional view showing the manufacturing process of the semiconductor device continued from FIG. 29;

FIG. 31 is a cross-sectional view showing the manufacturing process of the semiconductor device continued from FIG. 30;

FIG. 32 is a cross-sectional view showing the manufacturing process of the semiconductor device continued from FIG. 31;

FIG. 33 is a cross-sectional view showing the manufacturing process of the semiconductor device continued from FIG. 32;

FIG. 34 is a cross-sectional view showing the state of disturbance imparted to a non-selected cell in the writing at the array operation according to the second embodiment of the present invention;

FIG. 35 is a cross-sectional view showing the manufacturing process of the semiconductor device continued from FIG. 33;

FIG. 36 is a cross-sectional view showing the manufacturing process of the semiconductor device continued from FIG. 35;

FIG. 37 is a cross-sectional view for describing the state of impurity diffusion according to the second embodiment of the present invention;

FIG. 38 is a cross-sectional view showing a manufacturing process of a semiconductor device according to the third embodiment of the present invention;

FIG. 39 is a cross-sectional view showing the manufacturing process of the semiconductor device continued from FIG. 38;

FIG. 40 is a cross-sectional view showing the manufacturing process of the semiconductor device continued from FIG. 39;

FIG. 41 is a cross-sectional view showing the manufacturing process of the semiconductor device continued from FIG. 40;

FIG. 42 is a cross-sectional view showing the manufacturing process of the semiconductor device continued from FIG. 41;

FIG. 43 is a cross-sectional view showing the manufacturing process of the semiconductor device continued from FIG. 42;

FIG. 44 is a cross-sectional view showing a manufacturing process of a semiconductor device according to the fourth embodiment of the present invention;

FIG. 45 is a cross-sectional view showing the manufacturing process of the semiconductor device continued from FIG. 44;

FIG. 46 is a cross-sectional view showing the manufacturing process of the semiconductor device continued from FIG. 45;

FIG. 47 is a cross-sectional view showing the manufacturing process of the semiconductor device continued from FIG. 46;

FIG. 48 is a cross-sectional view showing the manufacturing process of the semiconductor device continued from FIG. 47;

FIG. 49 is a cross-sectional view showing a manufacturing process of a semiconductor device according to the fifth embodiment of the present invention;

FIG. 50 is a cross-sectional view showing the manufacturing process of the semiconductor device continued from FIG. 49;

FIG. 51 is a cross-sectional view showing the manufacturing process of the semiconductor device continued from FIG. 50;

FIG. 52 is a cross-sectional view showing the manufacturing process of the semiconductor device continued from FIG. 51;

FIG. 53 is a cross-sectional view showing the manufacturing process of the semiconductor device continued from FIG. 52;

FIG. 54 is a cross-sectional view showing a manufacturing process of a semiconductor device according to the sixth embodiment of the present invention;

FIG. 55 is a cross-sectional view showing the manufacturing process of the semiconductor device continued from FIG. 54;

FIG. 56 is a cross-sectional view showing the manufacturing process of the semiconductor device continued from FIG. 55;

FIG. 57 is a cross-sectional view showing the manufacturing process of the semiconductor device continued from FIG. 56;

FIG. 58 is a cross-sectional view showing the manufacturing process of the semiconductor device continued from FIG. 57;

FIG. 59 is a cross-sectional view showing the manufacturing process of the semiconductor device continued from FIG. 58;

FIG. 60 is a cross-sectional view showing a manufacturing process of a semiconductor device according to the seventh embodiment of the present invention;

FIG. 61 is a cross-sectional view showing the manufacturing process of the semiconductor device continued from FIG. 60;

FIG. 62 is a cross-sectional view showing the manufacturing process of the semiconductor device continued from FIG. 61;

FIG. 63 is a cross-sectional view showing the manufacturing process of the semiconductor device continued from FIG. 62;

FIG. 64 is a cross-sectional view showing the manufacturing process of the semiconductor device continued from FIG. 63;

FIG. 65 is a cross-sectional view showing the manufacturing process of the semiconductor device continued from FIG. 64;

FIG. 66 is a cross-sectional view showing the state of impurity diffusion in a manufacturing process of a semiconductor device according to the ninth embodiment of the present invention; and

FIG. 67 is a cross-sectional view showing the state of impurity diffusion in the manufacturing process of the semiconductor device according to the ninth embodiment of the present invention.

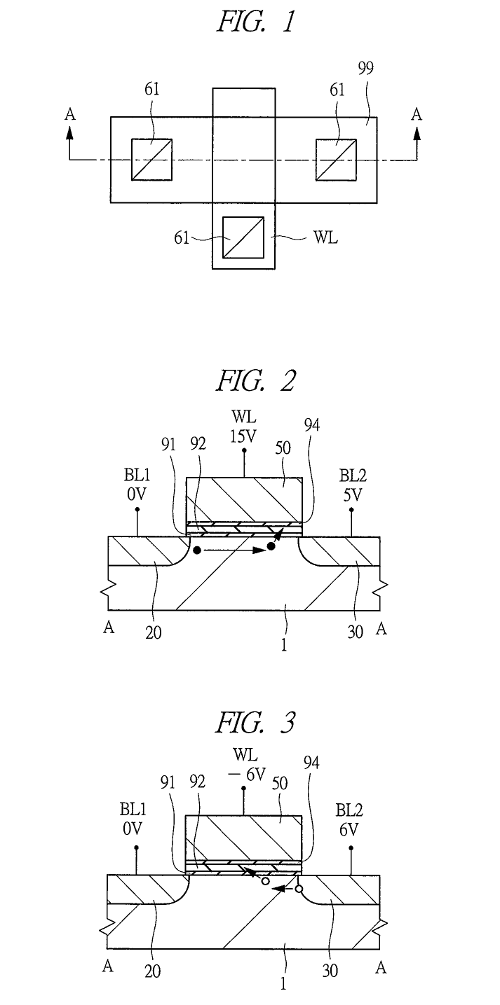

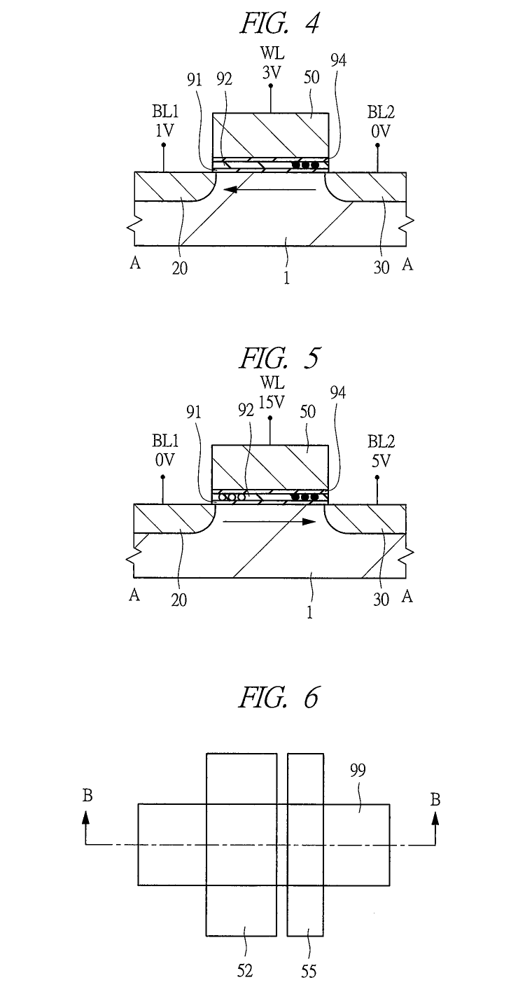

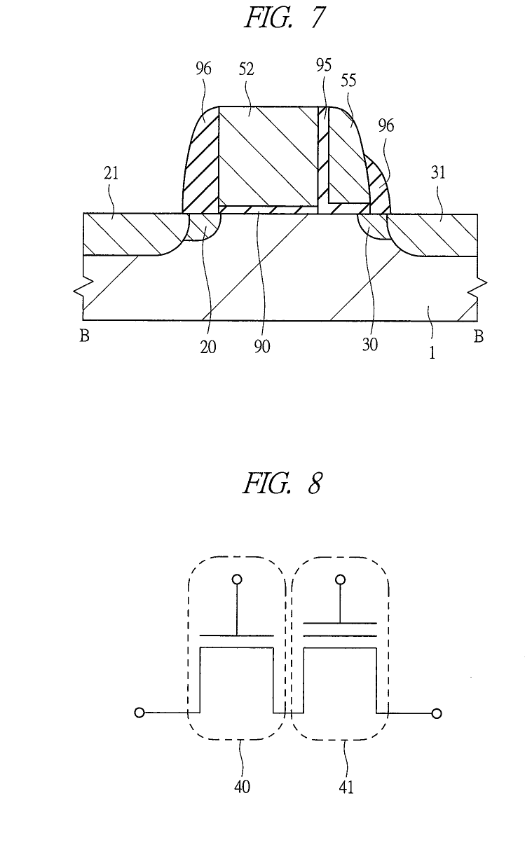

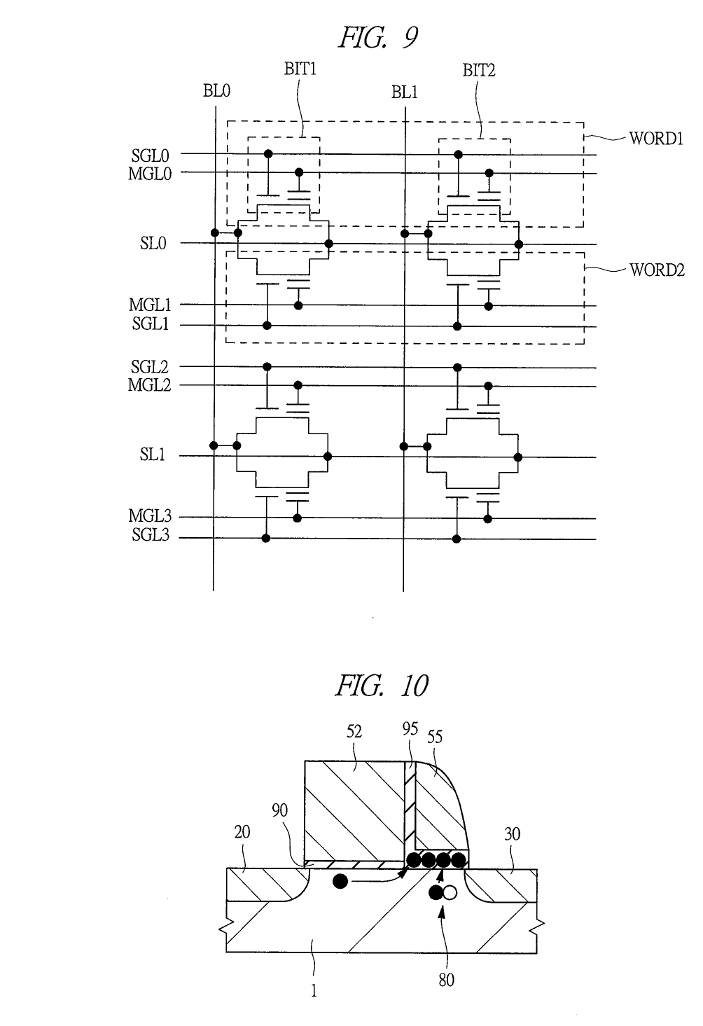

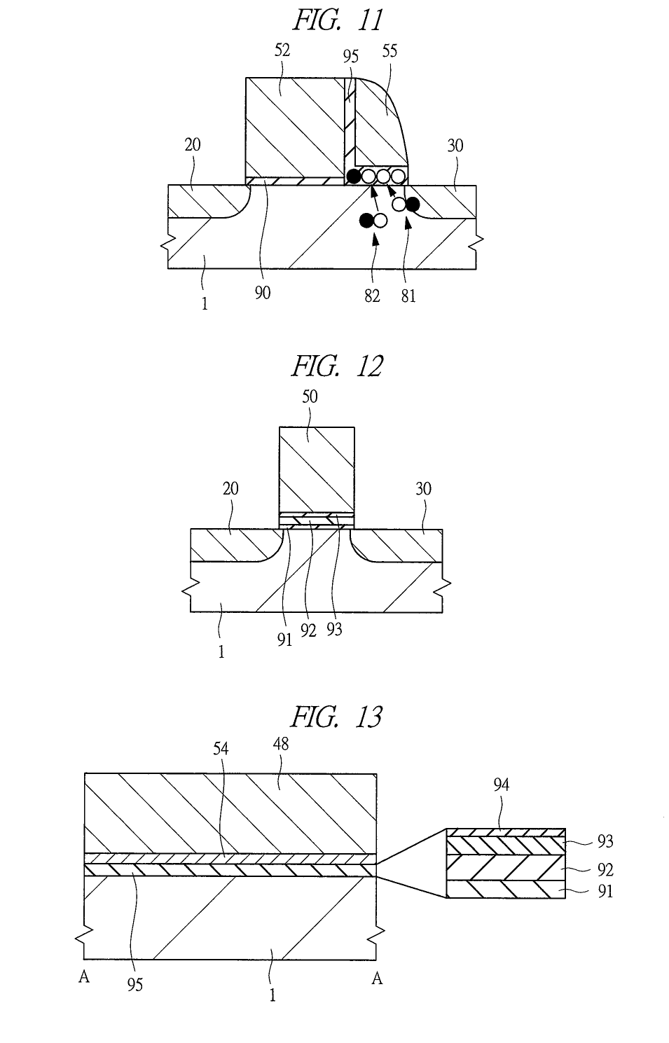

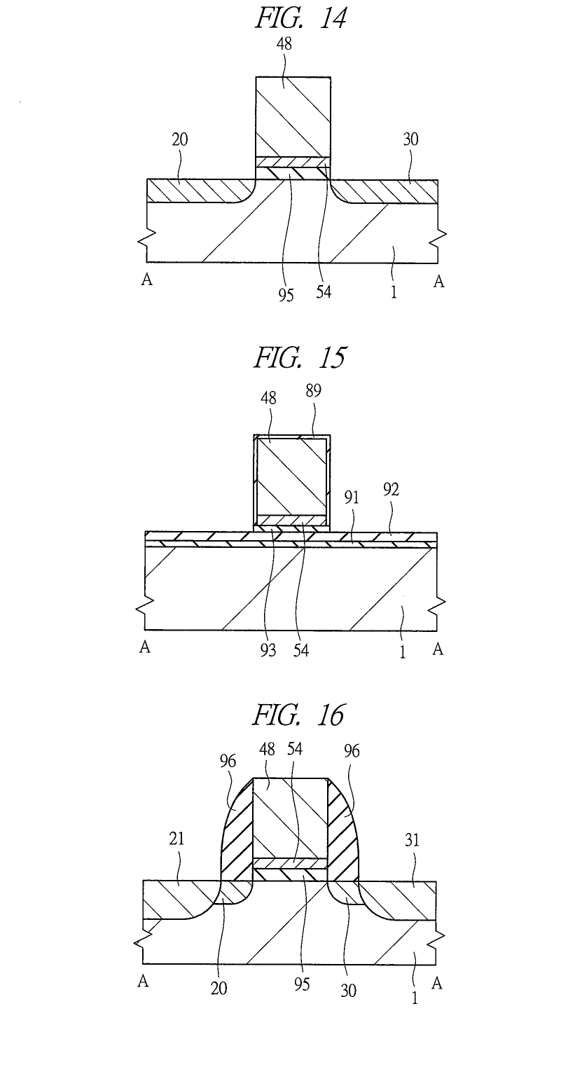

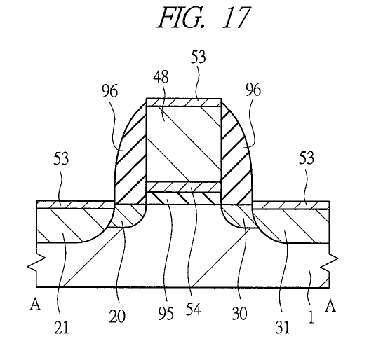

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiments, and the repetitive description thereof will be omitted.

The drawings are schematic, and the relation between thicknesses and planar dimensions, the ratios of the thicknesses of layers and the like should be determined in consideration of the following descriptions.

Also, the following embodiments exemplify devices and methods for realizing the technical ideas of the present invention, and the technical ideas of the present invention do not specify the materials, shapes, structures, arrangements, operating voltages and the like of the constituent parts to those in the embodiments.

### First Embodiment

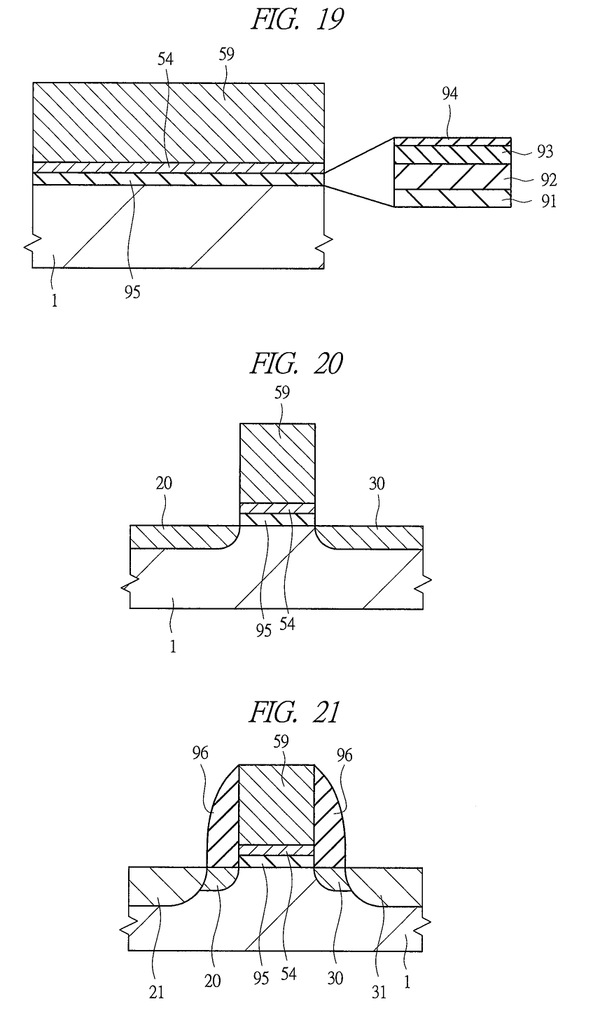

Hereinafter, the process of forming an NROM-type MONOS cell of the present embodiment will be described with reference to FIG. 19 to FIG. 23.

First, an isolation region (not shown) is formed in a main surface of a p type silicon substrate 1 by using a known shallow trench isolation process. Then, ion implantation of boron and activation annealing treatment are carried out, thereby forming a p type well region (not shown) in the surface of the silicon substrate 1. Next, as shown in FIG. 19, a gate insulating film 95 is formed on the silicon substrate 1. The gate insulating film 95 is made up of a four-layer film of a silicon oxide film 91, a silicon nitride film 92, a silicon oxynitride film 93 and a silicon oxide film 94.

Next, a non-doped amorphous silicon layer is deposited. Although the effects of the film thickness of the non-doped silicon layer will be described later, the layer is deposited to 10 nm in the present embodiment. Then, thermal treatment at 900° C. is carried out in an N₂ atmosphere for 30 minutes, thereby crystallizing the amorphous silicon layer to form a polysilicon layer 54, and a metal material electrode layer 59 made of TiN is deposited to 100 nm.

Next, as shown in FIG. 20, after the polysilicon layer 54 and the metal material electrode layer 59 are etched with using a resist as a mask, the gate insulating film 95 is etched, and arsenic is ion-implanted into the surface of the silicon substrate 1, thereby forming n⁻ type diffusion layers 20 and 30. In this process, arsenic is implanted also into the metal material electrode layer 59, but the TiN structure is an extremely high-density structure and the range distance (Rp) of the impurity in TiN is short, and therefore, arsenic is implanted merely into the part close to the upper surface of the TiN gate in the low-energy implantation. Moreover, since the TiN structure is an extremely high-density structure, diffusion of the impurity in TiN by the thermal treatment or the like is also extremely small. Therefore, even through the high-temperature thermal treatment thereafter, the impurity implanted into TiN does not diffuse to the non-doped silicon film almost at all. The implantation energy of arsenic herein is 5 to 10 keV, and the dose amount thereof is 2×10¹⁵ atom/cm².

The etching of the gate insulating film 95 is carried out by using HF and hot phosphoric acid. First, after the silicon oxide film which is the uppermost layer of the gate insulating film is etched by HF, the silicon oxynitride film 93 is etched by HF and hot phosphoric acid, the silicon nitride film 92 is etched by hot phosphoric acid, and the silicon oxide film 91 is etched by HF. In this process, there is a problem that the polysilicon layer 54 is also etched when the hot phosphoric acid is used. Therefore, before the treatment of hot phosphoric acid, the sidewalls of the polysilicon layer 54 have to be oxidized to about 3 to 5 nm. In this structure, the non-doped silicon layer is not in direct contact with p type and n type impurities, and therefore, even through this thermal oxidation step, impurities do not diffuse to the non-doped silicon layer. Moreover, although the TiN surface is also thinly oxidized in this process, the oxidized part can simply be removed by etching in the later processing of forming a contact onto the gate.

Note that, when the implantation of arsenic for forming the n⁻ type diffusion layers 20 and 30 is carried out before the etching of the silicon oxide film 91, the silicon oxide film 91 can be used as a through film of the ion implantation. Moreover, after the arsenic ion implantation, the silicon oxide film 91 is removed by hydrofluoric acid, and re-oxidation of about 1 nm in terms of the silicon oxide thickness is carried out. By this means, the part of the silicon oxide film 91, the silicon nitride film 92 and the silicon oxynitride film 93 that is exposed below the polysilicon gate can be thinly oxidized, the damage caused during the arsenic ion implantation can be recovered, and the reliability of the memory can be improved.

Next, as shown in FIG. 21, after a silicon oxide film having a film thickness of 100 nm is deposited on the silicon substrate 1 by the CVD method, the silicon oxide film is subjected to anisotropic etching, thereby forming sidewalls 96 on the sidewalls of the gate. Subsequently, after arsenic and phosphorous are ion-implanted to the surface of the silicon substrate 1, activation annealing is carried out to activate the arsenic and phosphorous, thereby forming diffusion layers 21 and 31 to be a source and a drain of the memory cell. Herein, the activation annealing is carried out at 1000° C. for about 10 seconds. As described above, the range distance (Rp) and diffusion thereafter of the implanted arsenic and phosphorous are small because TiN has the high-density structure. Therefore, in the case of the stacked gate of the non-doped silicon layer and the TiN layer, diffusion of impurities into the non-doped layer due to this activation annealing does not occur almost at all. Therefore, the diffusion layers can be activated without using a rapid-heating rapid-cooling process such as the laser annealing.

Next, as shown in FIG. 22, silicide layers 53 are formed on the surfaces of the diffusion layers 21 and 31, respectively, by a known salicide process. The silicide layers 53 are made of, for example, Co silicide. Note that the retention characteristic of the MONOS memory can be improved by adding the annealing treatment in a high-temperature H₂ atmosphere (about 700° C.) before the salicide process.

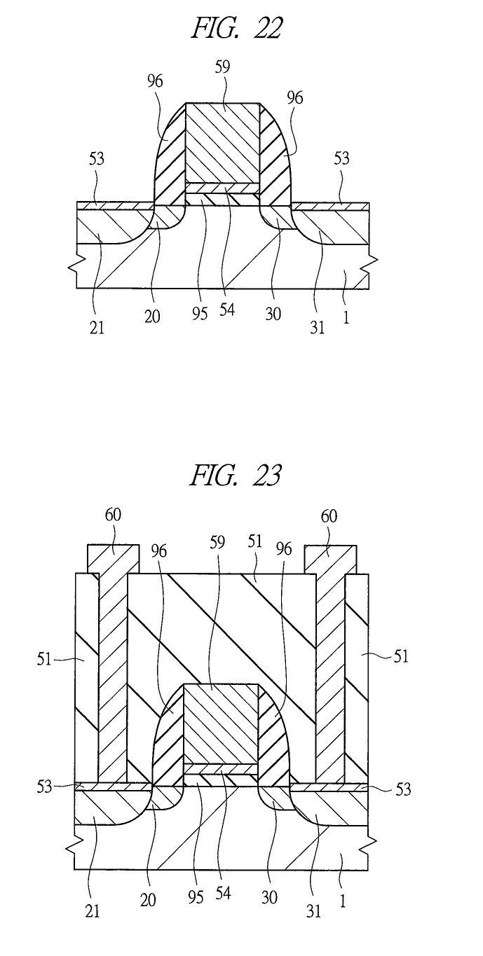

Next, as shown in FIG. 23, after a thick interlayer insulating film 51 is deposited on the silicon substrate 1, wiring 60 is formed on the interlayer insulating film 51 by a known wiring process. The NROM-type MONOS in which the gate has the stacked structure of non-doped silicon and metal is completed through the above steps.

As a conceivable example of the operating method of this memory, in the writing, for example, 10 V is applied to the gate, 8 V is applied to the source, 0 V is applied to the drain, 0 V is applied to the silicon substrate 1, and write is carried out by using channel hot electrons, and in the erasure, a positive voltage (for example, 12 V) is applied to the gate, and erasure is carried out by hole injection from the gate. Moreover, it is also conceivable that a negative voltage (for example, −12 V) is applied to the gate in the writing and a positive voltage (for example, 12 V) is applied to the gate in the erasure, so that the write/erasure are carried out by injecting electrons and holes from the gate. This gate structure makes the highly-efficient injection possible even in the case in which electrons are injected from the gate.

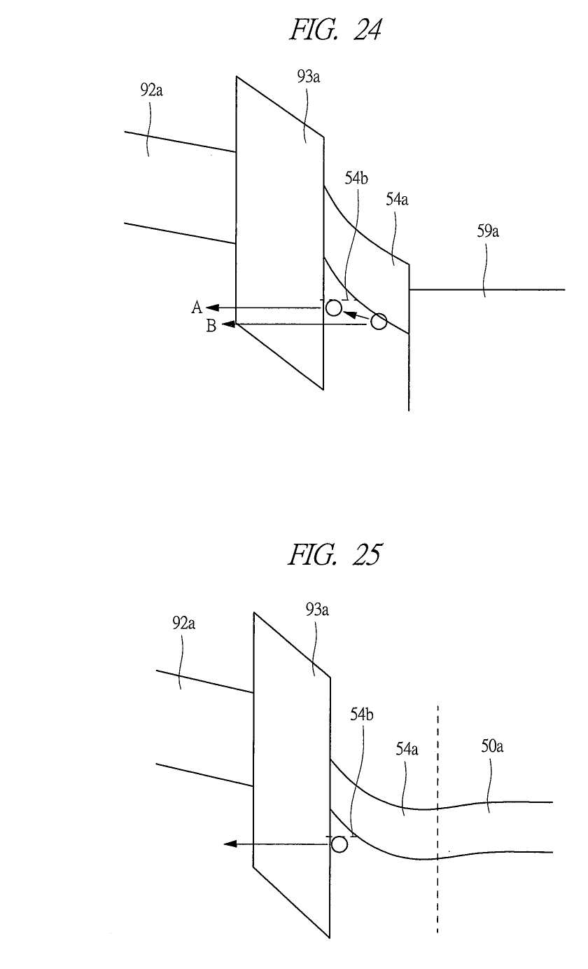

Herein, the reason why the stacked gate electrode of non-doped polysilicon and TiN (metal) of the present embodiment enables highly-efficient hole injection will be described. First, FIG. 25 shows a band diagram of the case in which a positive voltage is applied to a gate in the MONOS having the stacked gate electrode structure of non-doped polysilicon (impurity concentration: 3×10¹⁸/cm³ or more) and p⁺ type polysilicon as described in Patent Document 5, and FIG. 24 shows a band diagram of the case in which a positive voltage is applied to a gate in the MONOS having the stacked electrode of non-doped silicon and TiN (metal) of the present embodiment. In the band diagrams of FIG. 24 and FIG. 25, the reference numeral 92a corresponds to a silicon nitride film, the reference numeral 93a corresponds to a silicon oxynitride film, the reference numeral 54a corresponds to a non-doped polysilicon layer, the reference numeral 59a corresponds to a metal material electrode layer made of TiN, and the reference numeral 50a corresponds to a p⁺ type polysilicon electrode. Both in FIG. 24 and FIG. 25, the charge density of the non-doped polysilicon layer 54a is low, and therefore, the band thereof is bent. Also, both in FIG. 24 and FIG. 25, a quantum level 54b is formed between the silicon oxynitride film 93a and the polysilicon layer 54a. By virtue of this quantum level 54b, the barrier height of the silicon oxynitride film 93a viewed from the holes (represented by white circles in the diagrams) in the gate is reduced by the amount corresponding to the quantum level energy, the tunneling rate of the holes is increased compared with the MONOS using p⁺ type polysilicon or n⁺ type polysilicon gate that does not cause band bending almost at all, and highly efficient hole injection can be achieved. In the case of the structure of FIG. 25, the p⁺ type polysilicon electrode 50a serves as a supply source of holes.

In the case of FIG. 24, the gate does not have a supply source of holes like the p type semiconductor, but when a positive voltage is applied to the gate, the thermally excited carriers accelerated by the electric field applied to the non-doped polysilicon layer 54a cause the avalanche breakdown, and electron-hole pairs can be generated. Part of the holes among them loses energy and passes through the silicon oxynitride film 93a by the tunneling phenomenon from a bound state of the quantum level 54b (A in FIG. 24).

Another part of the holes can pass through the silicon oxynitride film 93a by the tunneling phenomenon from a position that is higher than the formed quantum level 54b in terms of energy (B in FIG. 24). This tunneling hole injection from the high-energy position realizes the hole injection more efficient than that of conventional techniques.

The lower the impurity concentration, the more likely the avalanche breakdown occurs even with a low electric field. This is because the band bending of polysilicon in the voltage application becomes larger and its distance becomes longer when the impurity concentration becomes lower and thus carriers are more likely to be accelerated, so that electron-hole pairs are easily generated. Generally, it is known that, when the concentration is about 10¹⁸/cm³ or less, avalanche breakdown occurs even with a low electric field of 0.1 MV/cm or less (for example, SEMICONDUCTOR DEVICES Physics and Technology 2nd Edition written by S. M. Sze, and Physics of VLSI Devices written by Mitsumasa KOYANAGI and Seigo KISHINO). If the concentration is in the range of about 10¹⁸/cm³ or more, the range in which the band bending occurs is shortened in terms of distance and the amount of band bending is also reduced, and therefore, acceleration of carriers becomes insufficient and avalanche breakdown is less likely to occur.

Note that, in the case of pn junction, breakdown due to the interband tunneling occurs in the range in which the concentration is about 10¹⁸/cm³ or more. However, this breakdown needs a larger electric field, and in a MOS structure, when holes are accumulated at the interface between the gate and the insulating film to some extent and the band bending becomes small, the interband tunneling phenomenon does not occur almost at all.

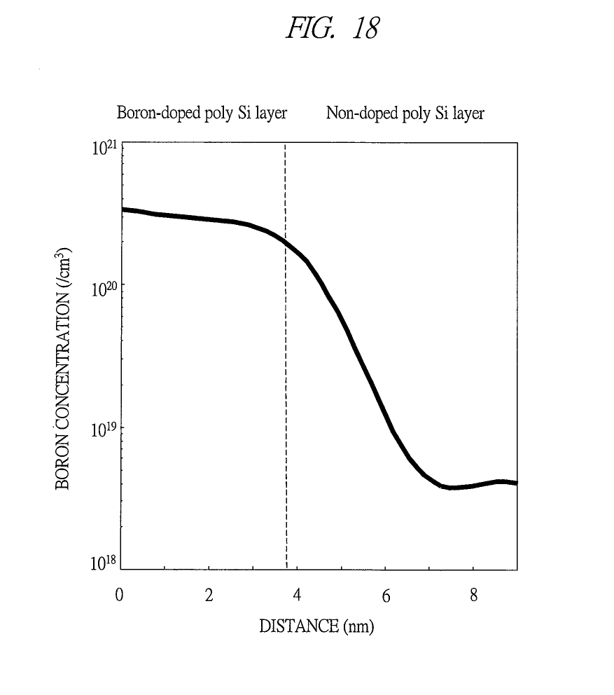

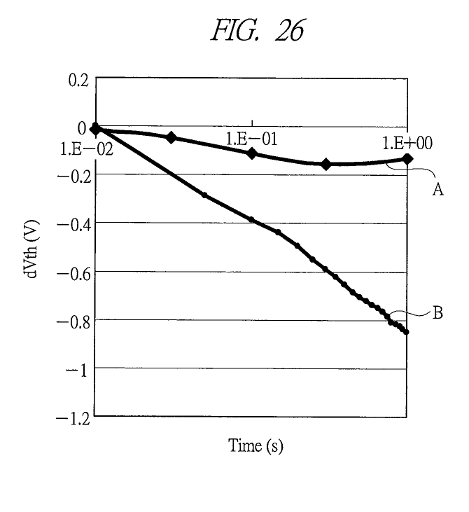

Experimental results showing the effects of the non-doped silicon/metal gate structure of the present embodiment are shown in FIG. 26. FIG. 26 shows the shifts in the flat band voltage and the threshold voltage (vertical axis) with respect to time (horizontal axis) of the case in which 12 V is applied to a gate and 0 V is applied to a silicon substrate in the MONOS in which a gate insulating film of an oxide film, a nitride film and an oxynitride film is formed in this order from the silicon substrate side and the structure of the gate is a stacked layer of non-doped polysilicon and p⁺ type polysilicon (A) or a stacked layer of non-doped polysilicon and TiN (B). The deposited film thickness of non-doped polysilicon is the same in both samples. Also, the highest thermal processing temperature during device formation is 400° C. or less, and the lower limit value of the boron concentration in the non-doped polysilicon in the stacked gate (A) of the non-doped polysilicon and the p⁺ type polysilicon is almost the same as that of FIG. 18 and is about 3×10¹⁸/cm³ to 5×10¹⁸/cm³. The boron concentration in the p⁺ type polysilicon is 10²⁰/cm³ or more.

It can be understood from this result that the gate (B) of the non-doped polysilicon/TiN (metal) structure overwhelmingly exceeds the gate (A) in the injection amount and injection speed of holes. This is because the holes generated by the avalanche breakdown are injected from the energy position higher than the quantum level in addition to the holes highly-efficiently injected with the assist by the quantum level as described above.

According to the above-described results, when the impurity concentration of the non-doped polysilicon layer is smaller than 10¹⁸/cm³, the more efficient hole injection from the gate than that of the case in which the conventional stacked structure is used can be realized.

Moreover, since the same is true of the case in which electrons are injected from the gate, the above-described mechanism can also be utilized in electron injection from the gate.

Note that, in the non-doped polysilicon/TiN (metal) stacked gate structure, the influence of the damage imparted to the insulating film during rewriting by the holes, which are generated by the avalanche breakdown in the gate, is small. This is because the energy of the holes generated by the avalanche breakdown is at most 1 eV or less and this value is half or less compared with the band offset of the Si/SiON film of the valence band side. Therefore, since the holes pass through the SiON film consistently by the tunneling phenomenon, the damage is small.

In the MONOS with the non-doped silicon/metal stacked gate structure, the time required for the hole injection erasure from the gate is short, and therefore, the time during which voltage stress is applied to the insulating film is short, and deterioration of the insulating film is suppressed well. Furthermore, when the band of the non-doped silicon layer of the gate bends in the charge retention, the electric field applied to the insulating film is weakened. By virtue of these effects, the data retention characteristic of the MONOS with the non-doped silicon/metal stacked gate structure is excellent.

Regarding the thickness of the non-doped silicon layer, the present inventors have confirmed the operation of the non-doped layer of up to about 80 to 100 nm by experiments and also have confirmed the effects of highly-efficient hole injection. However, when the non-doped silicon layer becomes too thick, the effect of gate depletion excessively works also when a gate voltage is applied in the reading, and defective reading is caused. On the other hand, when the thickness is smaller than 5 nm, the distance and size of the band bending of the non-doped layer become small, and the effects of the highly-efficient hole injection are reduced. When the reading characteristic and the like in the practical usage are taken into consideration, it is preferred to use the non-doped layer of about 5 nm or more and 100 nm or less.

### Second Embodiment

In the present embodiment, the structure and manufacturing method of a memory cell having a non-doped polysilicon/metal stacked gate structure capable of carrying out highly-efficient hole injection in a split gate type MONOS cell will be described.

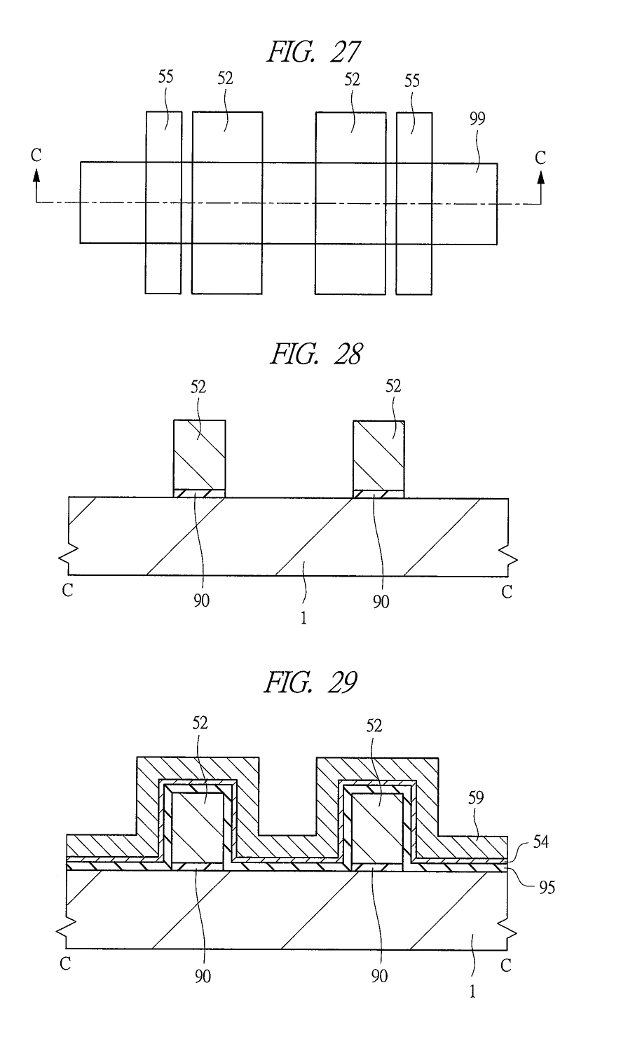

The drawings of FIG. 28 to FIG. 37 are cross-sectional views taken along the line C-C of FIG. 27. The reference numeral 52 of FIG. 27 corresponds to a select gate, the reference numeral 55 corresponds to a memory gate, and the reference numeral 99 corresponds to an active region. Note that descriptions here will be given by the use of the processing techniques equivalent to the so-called 0.13 μm generation.

First, as shown in FIG. 28, an isolation region (not shown) is formed in a main surface of a p type silicon substrate 1 by using a known shallow trench isolation process. Also, ion implantation of boron and activation annealing treatment are carried out, thereby forming a p type well region (not shown) in the surface of the silicon substrate 1. Next, after a gate insulating film 90 made up of a silicon oxide film having a film thickness of 2.5 nm is formed by thermally oxidizing the surface of the silicon substrate 1, a polysilicon layer having a film thickness of about 200 nm is deposited on the gate insulating film 90 by using the CVD method, and the polysilicon layer is subsequently dry-etched, thereby forming the select gate 52.

Next, as shown in FIG. 29, a gate insulating film 95 is formed on the silicon substrate 1. The gate insulating film 95 is made up of a four-layer film of a silicon oxide film 91, a silicon nitride film 92, a silicon oxynitride film 93 and a silicon oxide film 94.

Next, a non-doped polysilicon layer 54 made of non-doped polysilicon is deposited. A non-doped amorphous silicon layer may be used as the material of the polysilicon layer 54, and in that case, thermal treatment may be carried out at 900° C. in an N₂ atmosphere for 30 minutes after the deposition so as to crystallize the amorphous silicon layer into polysilicon. As the film thickness of the polysilicon layer 54 becomes larger, the erasure speed is more improved and Vth in the erasure saturation becomes lower. However, if the thickness is increased too much, the response when a voltage is applied to the memory gate becomes slow, and the reading characteristic is deteriorated. In the present embodiment, the thickness of the non-doped layer is, for example, 10 nm. Then, a metal material electrode layer 59 made of TiN is deposited to 100 nm on the silicon substrate 1.

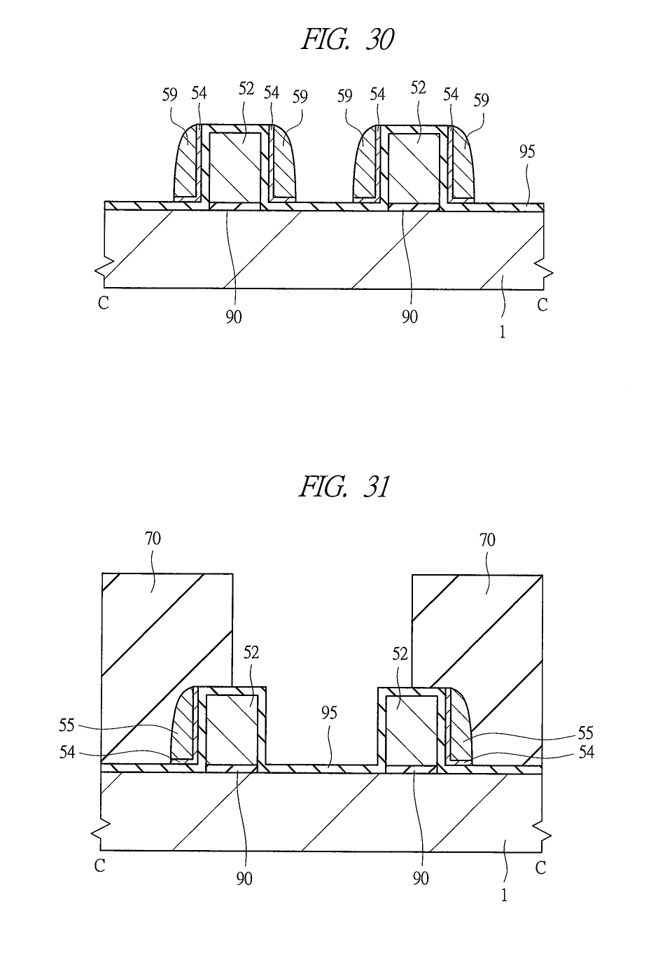

Next, the metal material electrode layer 59 and the polysilicon layer 54 are etched back, thereby forming sidewalls as shown in FIG. 30.

Next, as shown in FIG. 31, a memory gate on one of the sidewalls of the select gate 52 is removed by the dry etching using a photoresist film 70 as a mask, thereby leaving a memory gate 55 made up of the metal material electrode layer 59 only on the other sidewall.

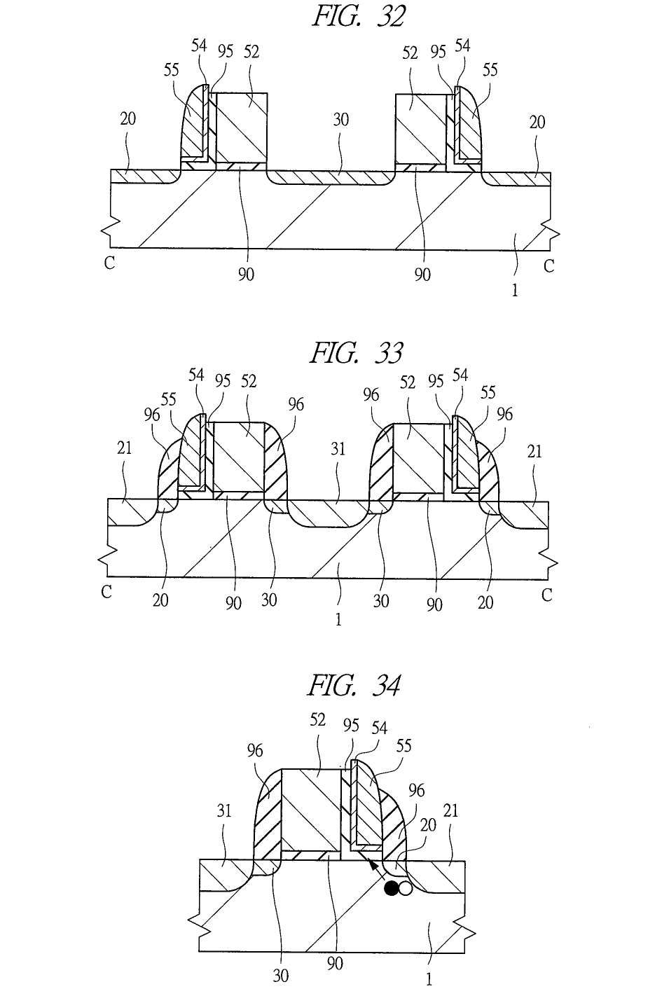

Next, as shown in FIG. 32, the gate insulating film 95 is etched, and arsenic is ion-implanted into the surface of the silicon substrate 1, thereby forming n⁻ type diffusion layers 20 and 30. The implantation energy of arsenic herein is 5 keV, and the dose amount thereof is 2×10¹⁵ atom/cm². The n⁻ type diffusion layers 20 and 30 are formed for causing the memory cell to have a LDD structure.

The etching of the gate insulating film 95 is carried out by using HF and hot phosphoric acid. First, after the silicon oxide film which is the uppermost layer of the gate insulating film is etched by HF, the silicon oxynitride film 93 is etched by HF and hot phosphoric acid, the silicon nitride film 92 is etched by hot phosphoric acid, and the silicon oxide film 91 is etched by HF. In this process, there is a problem that the polysilicon layer 54 is also etched when the hot phosphoric acid is used. Therefore, before the treatment of hot phosphoric acid, the sidewalls of the polysilicon layer 54 have to be oxidized to about 3 to 5 nm. In this structure, the polysilicon layer 54 is not in direct contact with p type and n type impurities, and therefore, even through this thermal oxidation step, impurities do not diffuse to the polysilicon layer 54. Moreover, although the TiN surface is also thinly oxidized in this process, the oxidized part can be removed by etching in the later processing of forming a contact onto the memory gate 55.

Herein, when the implantation of arsenic for forming the n⁻ type diffusion layers 20 and 30 is carried out before the etching of the silicon oxide film 91, the silicon oxide film 91 can be used as a through film of the ion implantation. Moreover, after the arsenic ion implantation, the silicon oxide film 91 is removed by hydrofluoric acid, and re-oxidation of about 1 nm in terms of the silicon oxide thickness is carried out. By this means, the part of the silicon oxide film 91, the silicon nitride film 92 and the silicon oxynitride film 93 that is exposed below the polysilicon gate can be thinly oxidized, the damage caused during the arsenic ion implantation can be recovered, and the reliability of the memory can be improved.

Next, as shown in FIG. 33, after a silicon oxide film having a film thickness of 100 nm is deposited on the silicon substrate 1 by the CVD method, the silicon oxide film is subjected to anisotropic etching, thereby forming sidewalls 96 on the sidewall of the select gate 52 and the sidewall of the memory gate. Subsequently, after arsenic and phosphorous are ion-implanted into the upper surface of the silicon substrate 1, the arsenic and phosphorous are activated, thereby forming diffusion layers 21 and 31 to be a source and a drain of the memory cell. For example, the arsenic is implanted at 30 keV and 1×10¹⁵/cm², and the phosphorous is implanted at 15 keV and 5×10¹³/cm². Herein, when RTA of a conventional technique is used in the activation annealing, thermal load at 950° C. to 1000° C. is applied for 10 seconds or more. If a stacked structure of a non-doped polysilicon layer and impurity-doped polysilicon is used as the gate electrode, the dopant diffuses from the impurity-doped polysilicon to the non-doped polysilicon due to the thermal diffusion also in this step. However, if a rapid-heating rapid-cooling process of μsec-order such as the laser annealing is used, the operation and reliability of the memory cell are deteriorated. Moreover, the disturbance resistance of the memory is also adversely affected. For example, when the writing is carried out to the upper left cell (the cell selected by MGL0, SGL0, SL0 and BL0) in the array of FIG. 9, the cell that is positioned in the lower right of the write cell and is not selected for write (the cell selected by MGL1, SGL1, SL0 and BL1) shares SL0 with the write cell. In the write of SSI, since charge is accelerated between the memory gate and the select gate and injected into the charge accumulating film, a high voltage is applied to the memory gate and the source thereof. Therefore, the high voltage is applied also to the source of the cell that is not selected for write. Accordingly, a strong electric field is generated between the diffusion layer and the silicon substrate, high-energy electron hole pairs are generated by the interband tunneling phenomenon and electric field acceleration phenomenon, and when the generated carriers are injected into the charge accumulating film, erroneous write or erroneous erasure occurs (FIG. 34). Such phenomenon becomes more serious as the pn junction created between the diffusion layer and the silicon substrate becomes steeper.

In the present embodiment, the memory gate 55 has the stacked gate structure of non-doped silicon and TiN. Also, since the implantation depth (Rp) of the impurities of the diffusion layers implanted into TiN and thermal diffusion of the impurities are extremely small as described above, even when activation annealing is carried out by RTA at 950° C. to 1000° C. for 10 seconds or more, there is no need to worry about the diffusion of the impurities in the gate, and the problems can be avoided.

Next, as shown in FIG. 35, silicide layers 53 are formed on the surfaces of the select gate 52 and the diffusion layers 21 and 31, respectively, by a known salicide process. The silicide layers 53 are made of, for example, Co silicide. Since the memory gate uses a TiN electrode, the resistance thereof is equivalent to or less than that of polysilicon silicide.

Note that the effect that the retention characteristic of the MONOS memory can be improved by adding the annealing treatment in a high-temperature H₂ atmosphere (about 700° C.) before the salicide process has been known. Further, since there is no need to worry about the diffusion of the impurities in the gate in the case in which the stacked gate electrode of non-doped silicon and TiN like the present embodiment is used, such high-temperature treatment can be carried out.

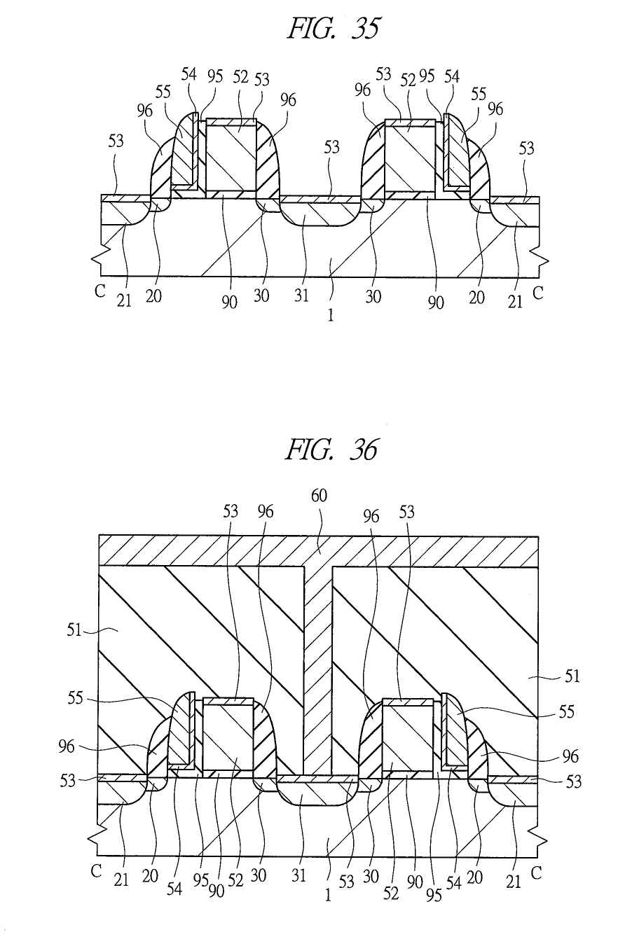

Next, as shown in FIG. 36, after a thick interlayer insulating film 51 is deposited on the silicon substrate 1, wiring 60 is formed on the interlayer insulating film 51 by a known wiring process. A MONOS type memory having a split gate structure capable of injecting holes from the gate electrode side is completed through the above steps.

As an example of the operating method/operating voltages of the memory described above, for example, in the writing, 1.5 V is applied to the select gate 52, 9 V is applied to the memory gate 55, 5 V is applied to the diffusion layer 21 of the memory gate side, 0 V is applied to the diffusion layer 31 of the select gate side, and 0 V is applied to the silicon substrate 1 so as to inject electrons into the silicon nitride film 92 by using the source side injection (SSI) method. In the erasure, for example, 12 V is applied to the memory gate 55, and 0 V is applied to the select gate 52, the diffusion layer 21 and the silicon substrate 1 so as to carry out the erasure by injecting holes from the memory gate 55.

Moreover, it is conceivable that, in the writing, a negative voltage (for example, −12 V) is applied to the memory gate 55, and in the erasure, a positive voltage (for example, 12 V) is applied to the memory gate 55 so as to carry out the writing and the erasure by injecting electrons and holes from the memory gate 55.

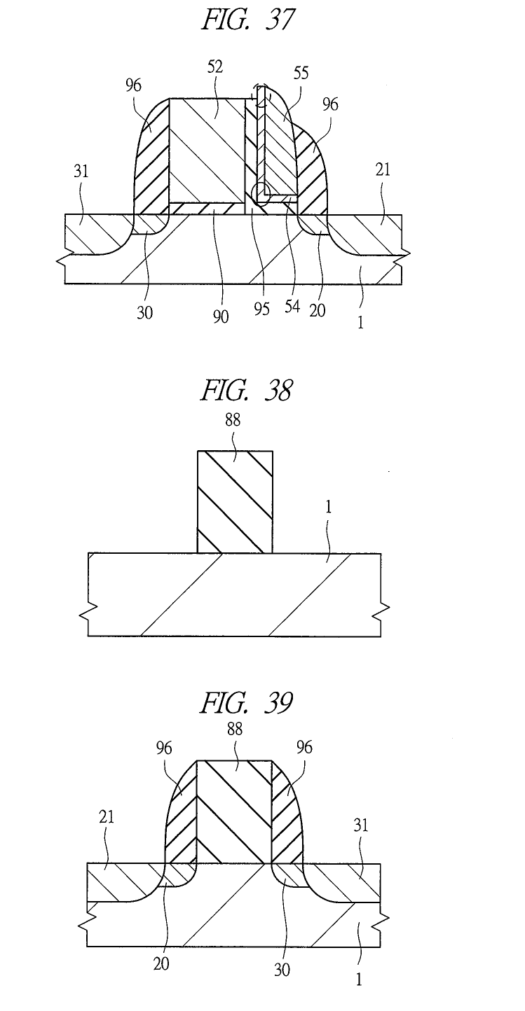

In the present embodiment, in the impurity implantation of the diffusion layer, the impurities are implanted also into an exposed part of an upper portion of the non-doped polysilicon layer 54 (the part shown by a broken-line circle of FIG. 37). However, when the range distance (depth Rp) into the polysilicon layer 54 in the impurity implantation is sufficiently small compared with the height of the select gate 52 (200 nm in the present embodiment) like the present embodiment, the impurity amount that reaches the corner part of the non-doped polysilicon layer 54 (the part shown by a solid-line circle of FIG. 37) is extremely small even after the thermal diffusion step thereafter. In the memory of the present embodiment, the part of the gate insulating film that is sandwiched by the memory gate 55 and the silicon substrate 1 mainly carries out the charge accumulation in the writing and the erasure, and therefore, when the impurity diffusion to the part of the polysilicon layer 54 that is deposited in parallel with the silicon substrate 1 is suppressed, highly-efficient hole injection can be realized. Moreover, when the thickness of the non-doped polysilicon layer 54 is small like the present embodiment, the diffusion speed of impurities becomes slow, and therefore, the amount of the impurities that diffuse in the non-doped polysilicon layer 54 toward the direction of the silicon substrate 1 is extremely small.

Moreover, after the n type diffusion layers 21 and 31 are formed in this structure, the exposed part of the polysilicon layer 54 shown by the broken-line circle of FIG. 37 is oxidized to about 3 nm, and the silicide layers 53 are then formed by the salicide process. By this means, the possibility of failure caused by short-circuit of the silicide of the select gate 52 and the memory gate 55 can be reduced. Note that, if both the select gate 52 and the memory gate 55 are silicon, short-circuit may occur above the gate if the volume of the silicide part expands when the surfaces of both the gates are silicided. In the case in which the memory gate 55 is TiN and is not silicided by the salicide process like the present embodiment, when the upper part of the non-doped polysilicon layer 54 is lightly oxidized, the possibility of the short circuit between the select gate 52 and the memory gate 55 can be reduced.

### Third Embodiment

In the present embodiment, the structure and manufacturing method of a memory cell having a non-doped polysilicon/metal stacked gate structure capable of carrying out highly-efficient hole injection in an NROM-type MONOS cell will be described.

Particularly, in the present embodiment, the processes and structure of the case in which a so-called gate-last process is used will be described.

First, an isolation region (not shown) is formed in a main surface of a p type silicon substrate 1 by using a known shallow trench isolation process. Also, ion implantation of boron and activation annealing treatment are carried out, thereby forming a p type well region (not shown) in the surface of the silicon substrate 1. Next, as shown in FIG. 38, after a silicon oxide film 88 made of silicon oxide is formed to 150 nm on the silicon substrate 1, the silicon oxide film 88 is patterned so as to have the shape of a gate with using a photoresist as a mask.

Then, as shown in FIG. 39, arsenic is implanted into the surface of the silicon substrate 1, thereby forming n⁻ type diffusion layers 20 and 30. Herein, the implantation energy of arsenic is, for example, 5 keV, and the dose amount thereof is 2×10¹⁵ atom/cm². The n⁻ type diffusion layers 20 and 30 are formed for causing the memory cell to have the LDD structure. Then, a silicon oxide film is deposited and etched back, thereby forming sidewalls 96. The sidewalls 96 use a silicon oxide film or a silicon nitride film. Then, arsenic and phosphorous are implanted into the main surface of the silicon substrate 1, thereby forming diffusion layers 21 and 31 to be n type diffusion layer regions. Then, activation annealing of, for example, about 10 seconds at 1000° C. is carried out by RTA, thereby activating the diffusion layer regions.

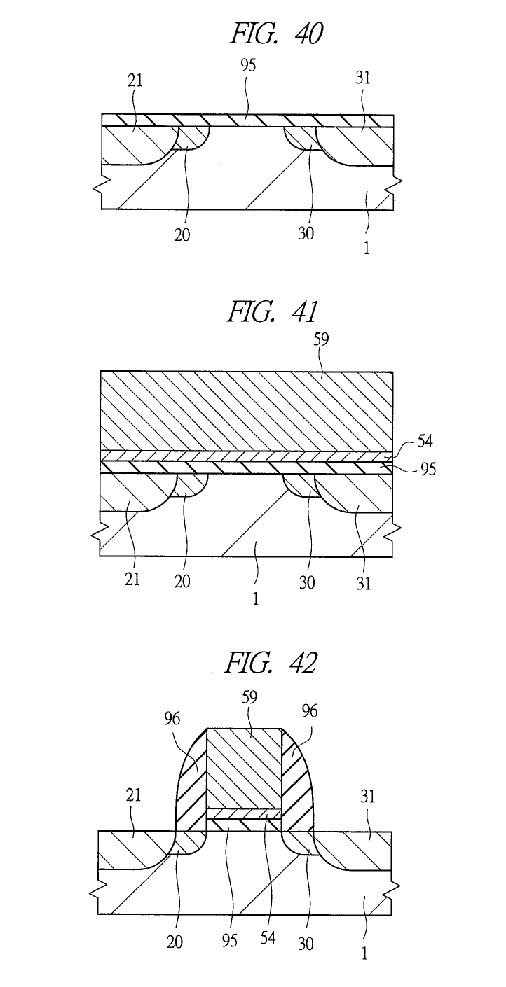

Next, as shown in FIG. 40, after the silicon oxide film 88 and the sidewalls 96 are removed by etching, a gate insulating film 95 is formed on the silicon substrate 1. The gate insulating film 95 is made up of a four-layer film in which four layers of a silicon oxide film 91, a silicon nitride film 92, a silicon oxynitride film 93 and a silicon oxide film 94 are sequentially stacked.

Next, as shown in FIG. 41, a non-doped polysilicon layer 54 and a metal material electrode layer 59 are sequentially deposited.

Next, as shown in FIG. 42, the metal material electrode layer 59 and the polysilicon layer 54 are etched with using a photoresist as a mask, and the gate insulating film 95 is removed by HF and hot phosphoric acid. When hot phosphoric acid is to be used, the sidewalls of the polysilicon layer 54 are oxidized to 3 to 5 nm. Then, arsenic ions are implanted into the silicon substrate 1, thereby forming diffusion layers 20 and 30 to be n⁻ type diffusion layer regions. Thereafter, a silicon oxide film to be sidewalls is deposited by the CVD method and then etched back, thereby forming sidewalls 96.

Next, as shown in FIG. 43, a silicide layer 53 is selectively formed on the diffusion layers 21 and 31, a thick interlayer insulating film 51 is deposited on the silicon substrate 1, and then wiring 60 is formed on the interlayer insulating film 51 by a known wiring process. A MONOS type memory having an NROM structure is completed through the above steps.

According to the manufacturing method of the present embodiment, the non-doped polysilicon/TiN (metal) stacked gate is formed after the diffusion layers are formed and the activation annealing is carried out, and therefore, the impurities do not enter TiN of the memory gate 55 at all in the formation of the diffusion layers, and impurity diffusion to the non-doped polysilicon layer can be prevented almost completely. As a result, highly-efficient hole injection from the gate can be realized.

Note that, although the silicon oxide film 88 is formed as a dummy gate in the present embodiment, a gate similar to the gate insulating film 95, the polysilicon layer 54 and the metal material electrode layer 59 may be formed as a dummy gate instead of the silicon oxide film 88, and after removing it after the formation of the diffusion layers 21 and 31, a gate made up of the gate insulating film 95, the polysilicon layer 54 and the metal material electrode layer 59 may be formed again.

### Fourth Embodiment

In the present embodiment, the structure and manufacturing method of a memory cell having a non-doped polysilicon/metal stacked gate structure capable of carrying out highly-efficient hole injection in an NROM-type MONOS cell will be described.

Particularly, in the present embodiment, the processes and structure of the case in which a so-called gate-last process is used will be described.

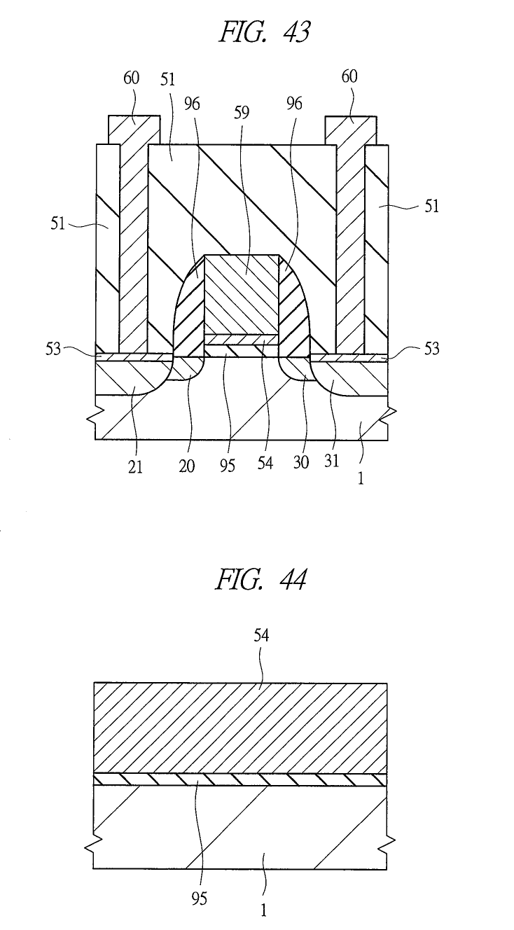

First, as shown in FIG. 44, an isolation region (not shown) is formed in a main surface of a p type silicon substrate 1 by using a known shallow trench isolation process. Also, ion implantation of boron and activation annealing treatment are carried out, thereby forming a p type well region (not shown) in the surface of the silicon substrate 1. Next, a gate insulating film 95 is formed on the silicon substrate 1. The gate insulating film 95 is made up of a four-layer film of a silicon oxide film 91, a silicon nitride film 92, a silicon oxynitride film 93 and a silicon oxide film 94. Then, a non-doped polysilicon layer 54 is deposited to 150 nm.

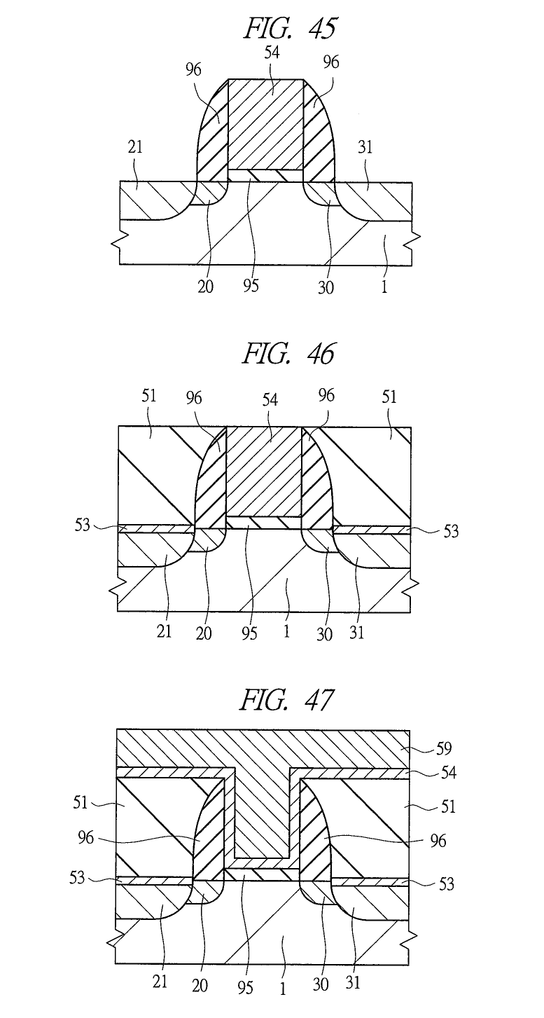

Next, as shown in FIG. 45, the polysilicon layer 54 is patterned so as to have the shape of a gate with using a photoresist as a mask, and the gate insulating film 95 is etched. Then, arsenic is implanted into the silicon substrate 1, thereby forming n⁻ type diffusion layers 20 and 30. Herein, the implantation energy of arsenic is, for example, 5 keV, and the dose amount thereof is 2×10¹⁵ atom/cm². Thereafter, a silicon oxide film is deposited and etched back, thereby forming sidewalls 96. Then, arsenic and phosphorous are implanted into the main surface of the silicon substrate 1, thereby forming diffusion layers 21 and 31 to be n type diffusion layer regions. After that, activation annealing of, for example, about 10 seconds at 1000° C. is carried out by RTA, thereby activating the diffusion layer regions.

Next, as shown in FIG. 46, after a silicide layer 53 is selectively formed on the diffusion layers 21 and 31 by a silicide process, an interlayer insulating film 51 (for example, a silicon oxide film by the CVD method) is deposited and polished by chemical mechanical polishing (CMP), thereby forming the shape as shown in FIG. 46.

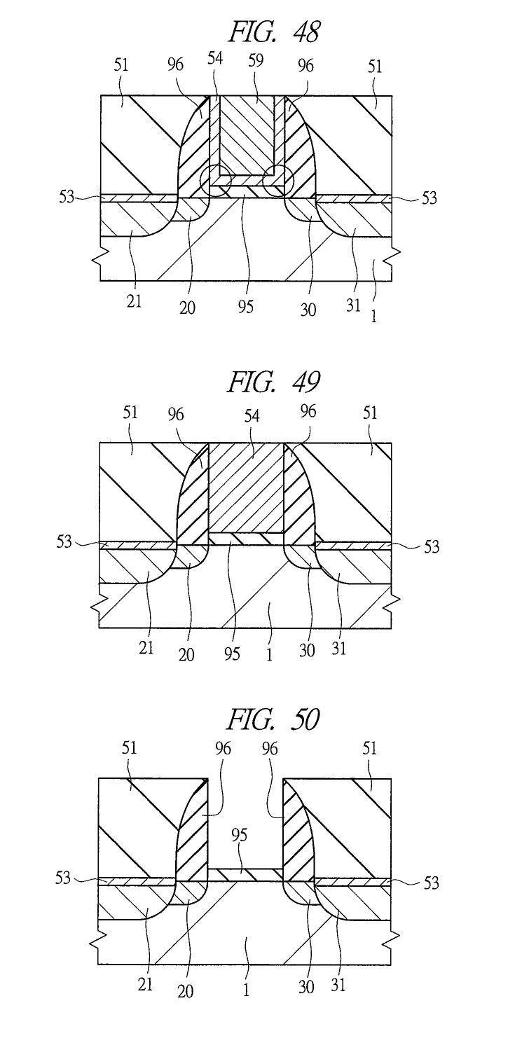

Next, as shown in FIG. 47, the polysilicon layer 54 is selectively subjected to trench etching, and then a non-doped polysilicon layer 54 and a metal material electrode layer 59 are deposited. Herein, the non-doped polysilicon layer 54 is deposited to 10 nm. Then, part of the polysilicon layer 54 and the metal material electrode layer 59 is polished by a CMP process, thereby forming the shape as shown in FIG. 48.

Thereafter, wiring which is conducted to the diffusion layers 20, 21, 30 and 31 and the gate is formed on the interlayer insulating film 51 by a known wiring process, and an NROM-type MONOS memory of the present embodiment is completed.

According to the manufacturing method of the present embodiment, since the non-doped polysilicon/TiN (metal) stacked gate is formed after the diffusion layers 20, 21, 30 and 31 are formed and the activation annealing is carried out, the impurities of the diffusion layers 20, 21, 30 and 31 do not enter TiN at all, and the impurity diffusion to the non-doped polysilicon layer 54 can be prevented almost completely. As a result, highly-efficient hole injection from the gate can be realized.

Moreover, since high-temperature thermal treatment such as activation annealing is not carried out after the metal material electrode layer 59 is deposited, a metal material having a low thermal resistance can also be used, and the range of material selection is expanded. Therefore, work function control of the gate becomes easier.

Moreover, the non-doped polysilicon layer 54 can have the shape of a sharp-edged corner like the parts surrounded by circles shown in FIG. 48. In the carrier injection from the gate, strong electric field concentration is generated in the vicinity of the corner part, so that more highly efficient injection can be carried out.

A point that should be taken into consideration in this manufacturing method is that, if the thickness of the polysilicon layer 54 is too large, the metal material electrode layer 59 cannot be embedded. Moreover, if the polysilicon layer 54 is thick, the region of the electric field effect that can be exerted by the metal material electrode layer 59 to the channel is reduced, which leads to the reduction in current in the reading. Particularly, in a scaled-down fine cell, the thickness of the polysilicon layer 54 has to be determined in consideration of the gate length thereof.

### Fifth Embodiment

In the present embodiment, the structure and manufacturing method of a memory cell having a non-doped polysilicon/metal stacked gate structure capable of carrying out highly-efficient hole injection in an NROM-type MONOS cell will be described.

Particularly, in the present embodiment, the processes and structure of the case in which a so-called gate-last process is used will be described.

First, as shown in FIG. 49, through the same process as that of the fourth embodiment, a gate made up of a non-doped polysilicon layer 54, diffusion layers 21 and 31 and n⁻ type diffusion layers 20 and 30 are formed on the main surface of a silicon substrate 1, a silicide layer 53 is selectively formed on the diffusion layers 21 and 31, and then an interlayer insulating film 51 is deposited and polished by a CMP process.

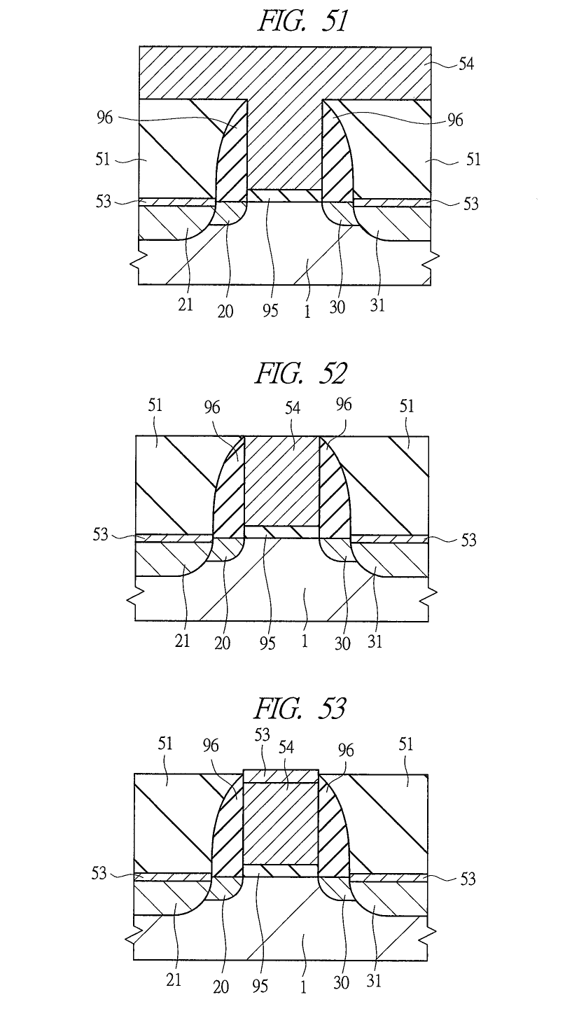

Next, as shown in FIG. 50, after the polysilicon layer 54 is selectively subjected to trench etching, a non-doped polysilicon layer 54 is deposited as shown in FIG. 51. Then, the polysilicon layer 54 is polished by a CMP process, thereby forming the shape as shown in FIG. 52.

Next, as shown in FIG. 53, a silicide layer 53 is selectively provided on the non-doped polysilicon layer 54.

Then, wiring conducted to the diffusion layers 20, 21, 30 and 31 and the gate is formed on the interlayer insulating film 51 by a known wiring process.

In this manner, the stacked gate of non-doped silicon and metal (silicide) can be formed as the gate electrode. Note that the height of the non-doped polysilicon layer 54 is set in consideration of the amount removed in the CMP process and the amount of the reaction between Si and a metal such as Co in the salicide process.

According to the manufacturing method of the present embodiment, since the non-doped polysilicon/silicide (metal) stacked gate is formed after the diffusion layers 20, 21, 30 and 31 are formed and the activation annealing is carried out, the impurities of the diffusion layers 20, 21, 30 and 31 do not enter the polysilicon at all, and the impurity diffusion to the non-doped polysilicon layer 54 can be prevented almost completely. As a result, highly-efficient hole injection from the gate can be realized.

### Sixth Embodiment

In the present embodiment, the structure and manufacturing method of a memory cell having a non-doped polysilicon/metal stacked gate structure capable of carrying out highly-efficient hole injection in a split gate type MONOS cell will be described. In the present embodiment, particularly, the processes in which the diffusion layer formation is carried out before the memory gate formation by using a dummy gate will be shown.

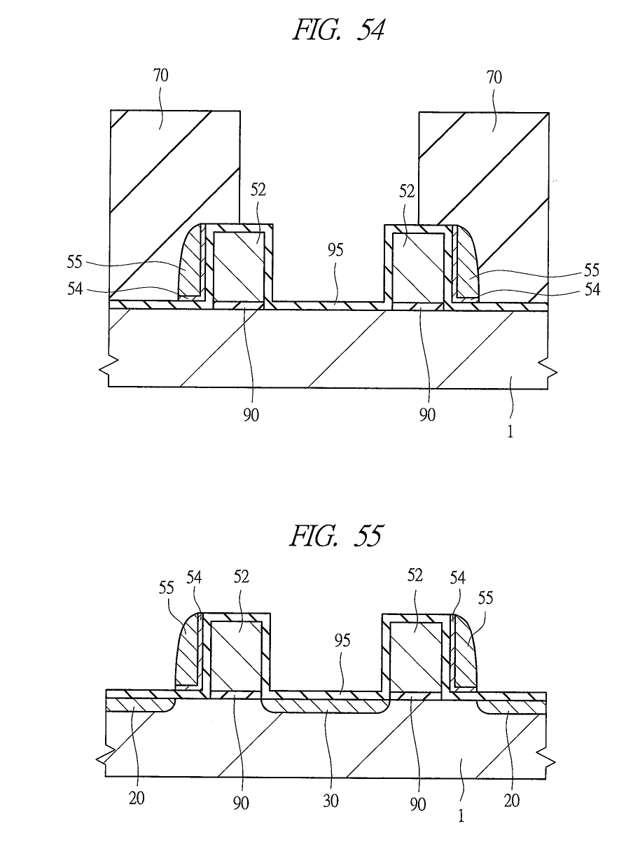

First, as shown in FIG. 54, through the same process as that of the fourth embodiment, a select gate is formed on a main surface of a p type silicon substrate 1, and a gate insulating film 95, a metal material electrode layer 59 and a non-doped polysilicon layer are sequentially deposited on the surface of the silicon substrate 1. Then, the metal material electrode layer 59 and the polysilicon layer are etched back by dry etching, thereby forming sidewall-shaped dummy memory gates 55 on the sidewalls of the select gate 52. Thereafter, the dummy memory gate on one of the sidewalls of the select gate 52 is removed with using a photoresist film 70 as a mask.

Next, as shown in FIG. 55, the photoresist film 70 is removed by ashing, and arsenic is ion-implanted into the upper surface of the silicon substrate 1, thereby forming diffusion layers 20 and 30 to be n⁻ type diffusion layers.

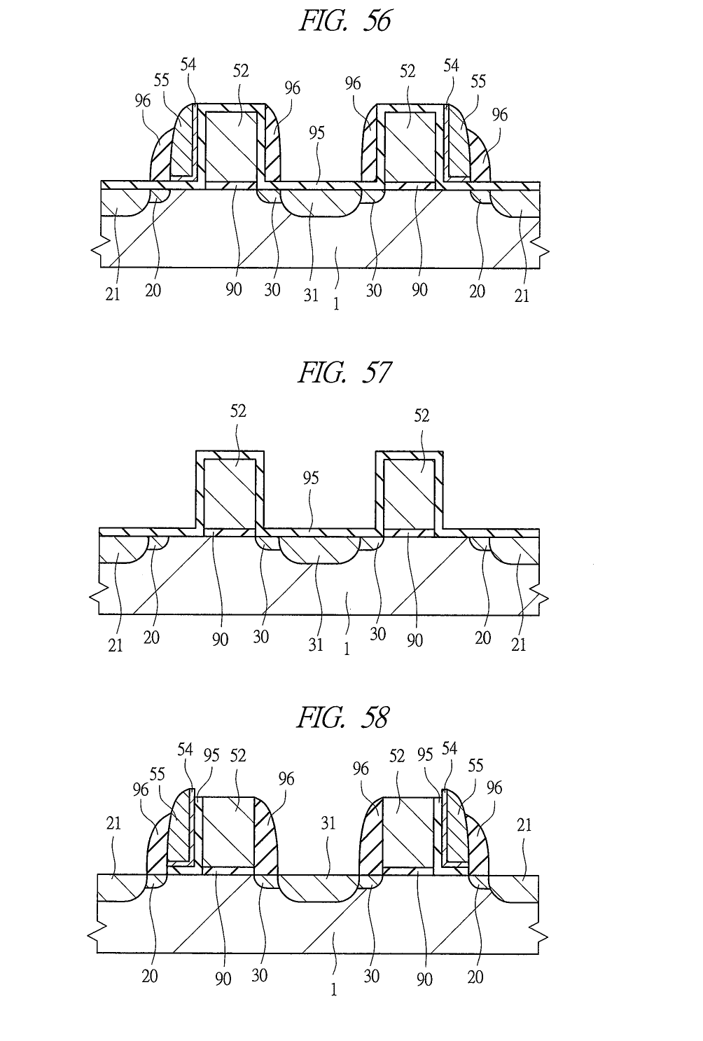

Next, as shown in FIG. 56, after a silicon oxide film having a film thickness of 100 nm is deposited on the silicon substrate 1 by the CVD method, the silicon oxide film is subjected to anisotropic etching, thereby forming sidewalls 96 on the sidewall of the select gate 52 and the sidewall of the memory gate 55. Subsequently, after arsenic and phosphorous are ion-implanted into the surface of the silicon substrate 1, activation is carried out to activate the arsenic and phosphorous, thereby forming diffusion layers 21 and 31 to be a source and a drain of the memory cell.

Next, as shown in FIG. 57, the sidewalls 96, the metal material electrode layer 59 and the polysilicon layer 54 are removed by etching.

Next, as shown in FIG. 58, a memory gate 55 and sidewalls 96 are formed again. More specifically, a polysilicon layer 54 is deposited to 10 nm on the silicon substrate 1, a TiN film is deposited to 100 nm, and then the sidewall-shaped memory gate 55 is formed by carrying out the etch back. Thereafter, the sidewall on one of the sidewalls of the select gate 52 is removed with using a resist as a mask, and the gate insulating film 95 is removed by using HF and hot phosphoric acid. Then, after a silicon oxide film to be a sidewall is deposited, the silicon oxide film is etched back, thereby forming a sidewall 96.

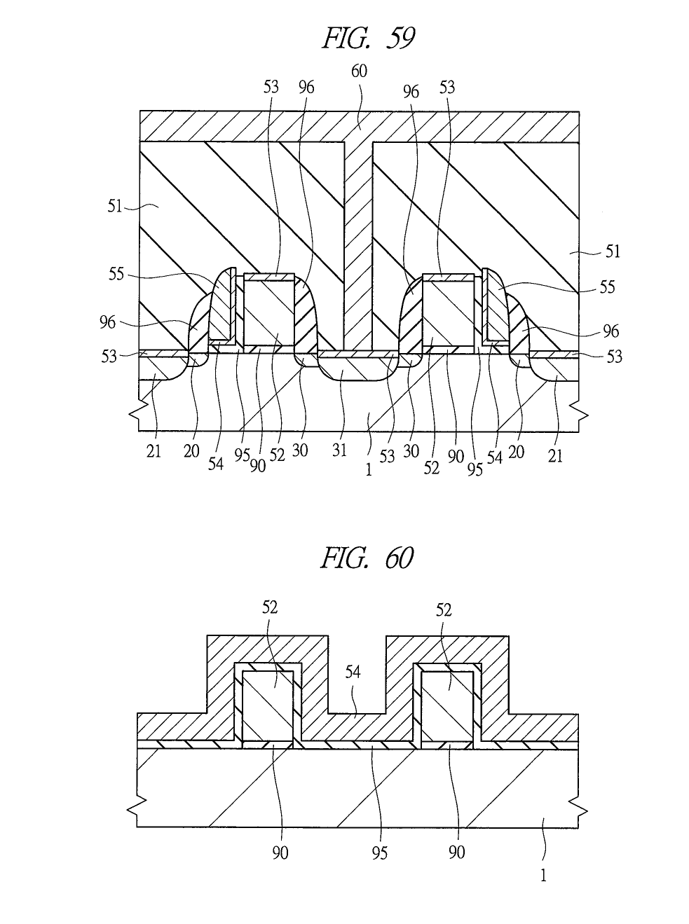

Next, as shown in FIG. 59, silicide layers 53 are formed on the surfaces of the select gate 52 and the diffusion layers 21 and 31, respectively, by a known salicide process. Since the memory gate 55 uses the TiN electrode, the resistance thereof is equivalent to or less than that of polysilicon silicide.

Note that the effect that the retention characteristic of the MONOS memory can be improved by adding the annealing treatment in a high-temperature H₂ atmosphere (about 700° C.) before the salicide process has been known. Further, since there is no need to worry about the diffusion of the impurities in the gate in the case in which the stacked gate electrode of non-doped silicon and TiN like the present embodiment is used, such high-temperature treatment can be carried out.

Then, after a thick interlayer insulating film 51 is deposited on the silicon substrate 1, wiring 60 is formed on the interlayer insulating film 51 by a known wiring process. A MONOS type memory having a split gate structure capable of injecting holes from the memory gate electrode side is completed through the above steps.

According to the manufacturing method of the present embodiment, since the non-doped polysilicon/TiN (metal) stacked gate is formed after the diffusion layers 20, 21, 30 and 31 are formed and the activation annealing is carried out, the impurities of the diffusion layers 20, 21, 30 and 31 do not enter TiN at all, and the impurity diffusion to the non-doped polysilicon layer 54 can be prevented almost completely. As a result, highly-efficient hole injection from the gate can be realized.

### Seventh Embodiment

In the present embodiment, the structure and manufacturing method of a memory cell having a non-doped polysilicon/metal stacked gate structure capable of carrying out highly-efficient hole injection in a split gate type MONOS cell will be described. In the present embodiment, particularly, the processes in which the diffusion layer formation is carried out before the memory gate formation by using a dummy gate will be shown.

First, as shown in FIG. 60, a select gate 52 having a gate insulating film 90 is formed on a main surface of a p type silicon substrate 1, a gate insulating film 95 is deposited on the surface of the silicon substrate 1, and then a non-doped polysilicon layer 54 is deposited to 100 nm.

Next, as shown in FIG. 61, the polysilicon layer 54 is etched back so as to form dummy memory gates 55, and the dummy memory gate 55 on one of the sidewalls of the select gate 52 is removed by dry etching using a photoresist film as a mask. Thereafter, arsenic is ion-implanted into the surface of the silicon substrate 1, thereby forming diffusion layers 20 and 30 to be n⁻ type diffusion layers. Herein, the implantation energy of the arsenic is 20 keV, and the dose amount thereof is 2×10¹⁵ atom/cm².

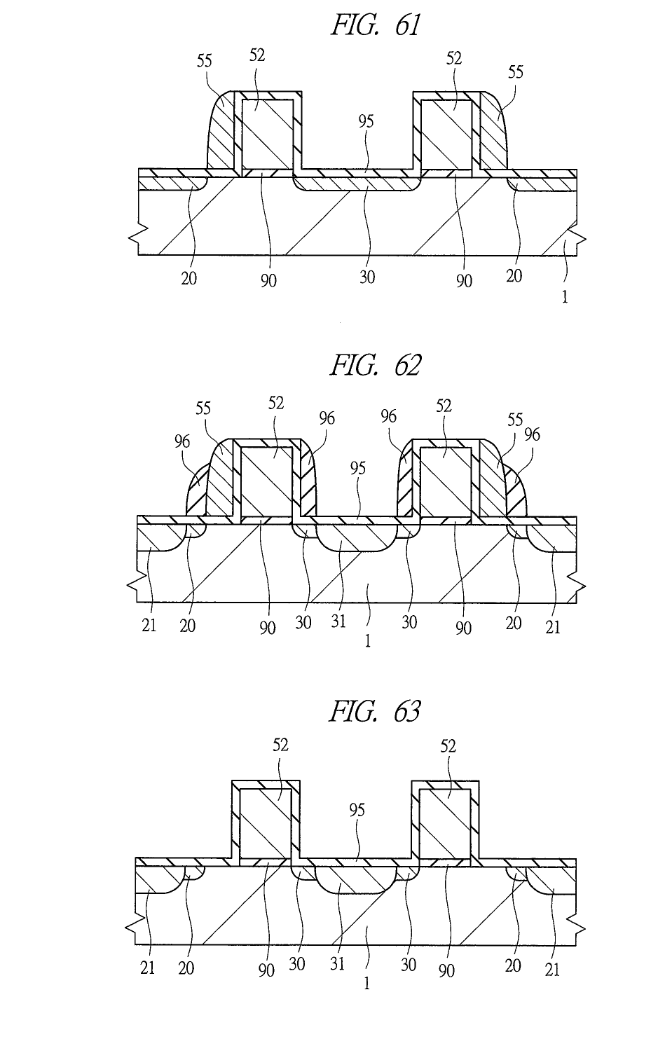

Next, as shown in FIG. 62, after a silicon oxide film having a film thickness of 100 nm is deposited on the main surface of the silicon substrate 1 by the CVD method, the silicon oxide film is subjected to anisotropic etching, thereby forming sidewalls 96 on the sidewall of the select gate 52 and the sidewall of the memory gate 55. Subsequently, after arsenic and phosphorous are ion-implanted into the surface of the silicon substrate 1, activation is carried out to activate the arsenic and phosphorous, thereby forming diffusion layers 21 and 31 to be a source and a drain of the memory cell. For example, the arsenic is implanted at 30 keV and 3×10¹⁵/cm², and the phosphorous is implanted at 20 keV and 5×10¹³/cm². In the activation annealing, treatment is carried out at 950° C. to 1000° C. for about 10 seconds by using RTA of a conventional technique.

Next, as shown in FIG. 63, the sidewalls 96 and the memory gates 55 are removed by etching.

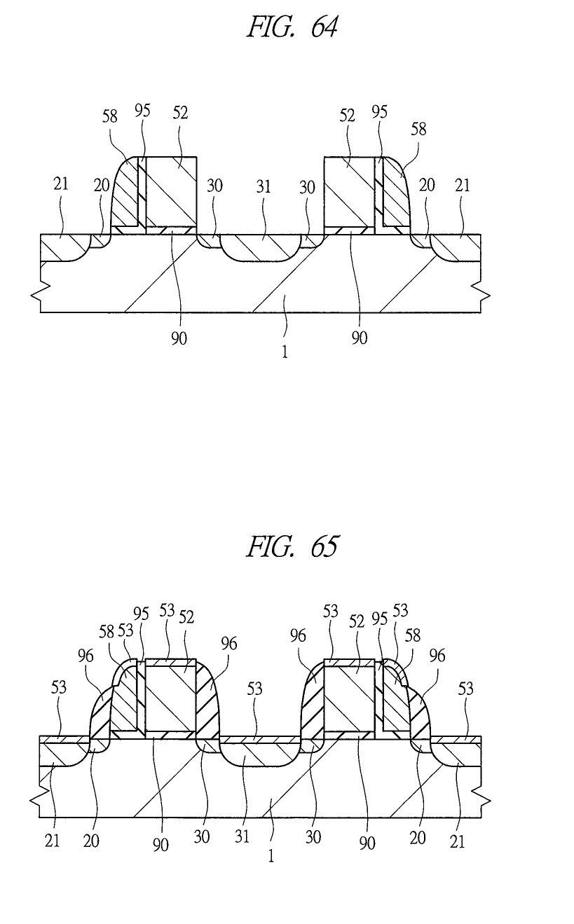

Subsequently, as shown in FIG. 64, a non-doped polysilicon layer is deposited to 100 nm and then etched back, thereby forming sidewall-shaped memory gates 58. Then, the sidewall on one of the sidewalls of the select gate is removed with using a resist as a mask, and the gate insulating film 95 is removed by using HF and hot phosphoric acid.

Then, as shown in FIG. 65, a silicon oxide film is deposited on the main surface of the silicon substrate 1 and then etched back, thereby forming sidewalls 96. Then, silicide layers 53 are formed on the surfaces of the select gate 52, the diffusion layers 21 and 31 and the memory gate 58, respectively, by a known salicide process.

Note that the effect that the retention characteristic of the MONOS memory can be improved by adding the annealing treatment in a high-temperature H₂ atmosphere (about 700° C.) before the salicide process has been known. Further, since there is no need to worry about the diffusion of the impurities in the gate in the case in which only the non-doped silicon like the present embodiment is used for the gate electrode, such high-temperature treatment can be carried out.

Then, although it is not shown in the drawings, after a thick interlayer insulating film is deposited on the silicon substrate 1, wiring is formed on the interlayer insulating film by a known wiring process. A MONOS type memory of the split gate structure capable of injecting holes from the gate electrode side is completed through the above steps.

According to the manufacturing method of the present embodiment, since the non-doped polysilicon/TiN (metal) stacked gate is formed after the diffusion layers 20, 21, 30 and 31 are formed and the activation annealing is carried out, the impurities of the diffusion layers 20, 21, 30 and 31 do not enter TiN at all, and the impurity diffusion to the non-doped polysilicon layer 54 can be prevented almost completely. As a result, highly-efficient hole injection from the gate can be realized.

### Eighth Embodiment

In the first to seventh embodiments above, it has been described that the impurity concentration in the non-doped polysilicon of the gate is desirably 10¹⁸/cm³ or less, and ideally, the hole injection efficiency is more enhanced when the concentration comes close to 0/cm³.

When the impurity concentration of the polysilicon layer of the gate is further lowered, the gate is depleted, and the initial threshold voltage of the MONOS transistor is lowered. Therefore, compared with MONOS having a high initial threshold voltage, the threshold voltage of the memory is more lowered when the same amount of holes are accumulated in an erasure state (hole accumulated state). As a result, even at a memory gate voltage of 0 V, a large reading current can be obtained. The increase in the reading current enables high-speed operation of the module, for example, when the MONOS is used for a memory that is mounted together with a microcomputer.

On the other hand, there is also a case in which a high reading current is not required in the erasure state as described above or a circuit in which the threshold voltage of the memory has to be at a position higher than 0 V even in the erasure state.

In that case, MONOS having a high threshold voltage may be utilized by setting the impurity concentration of the non-doped layer of the non-doped silicon/metal stacked gate structure to about 10¹⁸ to 5×10¹⁹/cm³. As a matter of course, due to the increase in the impurity concentration of the gate, the amount of the holes generated by avalanche breakdown is reduced, and the band bending amount and the band bending distance in the voltage application are also reduced, and therefore, the hole injection efficiency is lowered. Nevertheless, compared with the p⁺ type and n⁺ type polysilicon gates (>10²⁰/cm³), the effect of gate depletion is observed in the voltage application if the concentration is 10¹⁸ to 5×10¹⁹/cm³, and holes can be highly efficiently injected into the charge accumulating film with the assist of the quantum level formed by the band bending of the polysilicon in the gate.

As the manufacturing method thereof, in the processes shown in the above embodiments, the impurity concentration is simply adjusted in the deposition of the polysilicon of the gate.

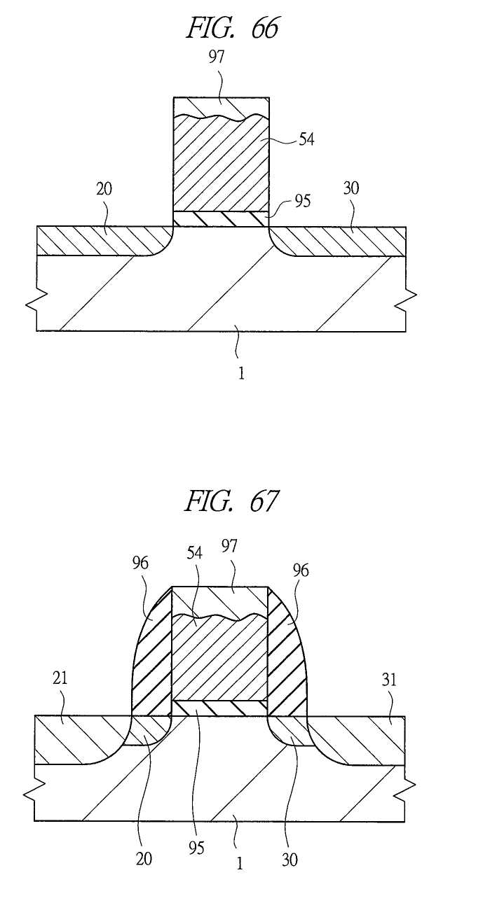

Meanwhile, as shown in FIG. 66 and FIG. 67, there is also a simple formation method with a small number of steps. Specifically, an impurity concentration-adjusted gate can be formed by adjusting the concentration of the impurity implanted into a gate upper portion 97 in the formation of the diffusion layers 20 and 30 or 21 and 31 so that the concentration of the gate after activation annealing becomes about 10¹⁸ to 5×10¹⁹/cm³. Particularly, effects are exerted when the part of the gate polysilicon layer 54 close to the gate insulating film 95 (region that is about 10 nm from the interface between the insulating film and the gate) has the impurity concentration of about 10¹⁸ to 5×10¹⁹/cm³. A similar manufacturing method can be employed also in the formation of a split gate type MONOS memory.

### Ninth Embodiment

A manufacturing method pursuant to the non-doped polysilicon/metal stacked gate structures shown above will be described. This process is a simple formation method with a small number of steps. The case of NROM type is taken as an example for the description. As shown in FIG. 66 and FIG. 67, after a gate is formed, in the formation of the diffusion layers 20, 21, 30 and 31, the concentration of the impurities implanted into a gate upper portion 97 is adjusted so that the impurity concentration of the gate after activation annealing becomes low, thereby forming an impurity concentration-adjusted gate. Particularly, effects are exerted when the part of the gate polysilicon layer 54 close to the gate insulating film 95 (region that is about 10 nm from the interface between the insulating film and the gate) has a sufficiently low impurity concentration by adjusting also the activation annealing time.

Thereafter, similarly to the embodiments described above, after a thick interlayer insulating film is deposited, wiring is formed on the interlayer insulating film by a known wiring process. A MONOS type memory capable of injecting holes from the gate electrode side is completed through the above steps. The same is true of the formation of split gate type MONOS.

According to the present embodiment, the structure pursuant to the non-doped polysilicon/metal stacked structure can be formed by extremely simple processes. However, sufficient attention has to be paid for the impurity concentration in the diffusion layer formation and the following thermal processes.

### Tenth Embodiment

In the embodiments above, the embodiments of the MONOS type memories using a silicon nitride film as a charge accumulating film have been shown. The present invention is effective also in a floating gate type memory using polysilicon as a charge accumulating film when the rewriting using carrier injection from a gate is carried out.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be applied to a semiconductor storage device having a non-volatile memory.

1. A semiconductor device including a memory cell formed on a main surface of a semiconductor substrate of a first conductivity type,
wherein the memory cell comprises:
a gate electrode formed on the semiconductor substrate via a gate insulating film; and
a source region and a drain region formed in the semiconductor substrate in a vicinity of the gate electrode and respectively made up of semiconductor regions of a second conductivity type,
the gate insulating film is made up of at least an electric potential barrier film and a charge retaining film stacked on the electric potential barrier film, and
the gate electrode includes a polysilicon layer having an impurity concentration of 5×10¹⁹/cm³ or less and a metal material electrode layer formed on the polysilicon layer.

2. The semiconductor device according to claim 1,
wherein the impurity concentration in the polysilicon layer is 1×10¹⁸/cm³ or more.

3. The semiconductor device according to claim 1,
wherein the impurity concentration in the polysilicon layer is 1×10¹⁸/cm³ or less.

4. The semiconductor device according to claim 1,
wherein the metal material electrode layer contains TiN.

5. The semiconductor device according to claim 1,
wherein the metal material electrode layer contains silicide.

6. The semiconductor device according to claim 1,
wherein the polysilicon layer has a thickness of 5 nm to 100 nm.

7. The semiconductor device according to claim 1,
wherein write and erasure with respect to a storage device are carried out by injecting charge from the gate electrode.

8. The semiconductor device according to claim 1,
wherein erasure with respect to a storage device is carried out by injecting holes from the gate electrode.

9. A semiconductor device including a memory cell formed on a main surface of a semiconductor substrate of a first conductivity type,
wherein the memory cell comprises:
a select gate formed on the semiconductor substrate via a first gate insulating film;
a memory gate formed on one of sidewalls of the select gate and insulated from the select gate and the semiconductor substrate via a second gate insulating film;
a source region formed in the semiconductor substrate in a vicinity of the select gate and made up of a semiconductor region of a second conductivity type; and
a drain region formed in the semiconductor substrate in a vicinity of the memory gate and made up of a semiconductor region of the second conductivity type,
the second gate insulating film is made up of at least an electric potential barrier film and a charge retaining film stacked on the electric potential barrier film, and
the memory gate includes a polysilicon layer having an impurity concentration of 5×10¹⁹/cm³ or less and a metal material electrode layer formed on the polysilicon layer.

10. The semiconductor device according to claim 9,
wherein the impurity concentration in the polysilicon layer is 1×10¹⁸/cm³ or more.

11. The semiconductor device according to claim 9,
wherein the impurity concentration in the polysilicon layer is 1×10¹⁸/cm³ or less.

12. The semiconductor device according to claim 9,
wherein the metal material electrode layer contains TiN.

13. The semiconductor device according to claim 9,
wherein the metal material electrode layer contains silicide.

14. The semiconductor device according to claim 9,
wherein the polysilicon layer has a thickness of 5 nm to 100 nm.

15. The semiconductor device according to claim 9,
wherein write and erasure with respect to a storage device are carried out by injecting charge from the memory gate.

16. The semiconductor device according to claim 9,
wherein erasure with respect to a storage device is carried out by injecting holes from the memory gate.

17-30. (canceled)
